(19) United States
(12) Patent Application Publication
(10) Pub. No.: US 2025/0311598 A1
(43) Pub. Date: Oct. 2, 2025

(54) DISPLAY PANEL, METHOD OF MANUFACTURING DISPLAY PANEL, AND DISPLAY DEVICE

(71) Applicant: BOE TECHNOLOGY GROUP CO., LTD., Beijing (CN)

(72) Inventors: Wenxiu ZHU, Beijing (CN); Shiming SHI, Beijing (CN); Song ZHANG, Beijing (CN); Mingche HSIEH, Beijing (CN)

(21) Appl. No.: 18/867,166

(22) PCT Filed: Mar. 28, 2024
(86) PCT No.: PCT/CN2024/084487

§ 371 Date: Nov. 19, 2024

(51) Int. Cl. H10K 59/80; H10K 59/12; H10K 59/40

(52) U.S. Cl. CPC H10K 59/879; H10K 59/1201; H10K 59/40; H10K 59/8792

(57) ABSTRACT

A display panel, a method of manufacturing a display panel, and a display device are provided. The display panel includes: a base substrate; a plurality of sub-pixels arranged in array in first direction and second direction and including a plurality of sharing sub-pixels and peeping prevention sub-pixels; a light shielding layer defining a plurality of opening regions; and a lens structure. The peeping prevention sub-pixel includes a peeping prevention pixel opening. An orthographic projection of opening region on base substrate at least partially overlaps with orthographic projection of at least one peeping prevention pixel opening on base substrate. An orthographic projection of at least one peeping prevention pixel opening on base substrate falls within an orthographic projection of lens structure on base substrate, and the orthographic projection of lens structure on base substrate at least partially overlaps with an orthographic projection of at least one opening region on base substrate.

### CROSS-REFERENCE TO RELATED APPLICATION

This application is a Section 371 National Stage Application of International Application No. PCT/CN2024/084487, filed on Mar. 28, 2024, entitled “DISPLAY PANEL, METHOD OF MANUFACTURING DISPLAY PANEL, AND DISPLAY DEVICE”, the content of which is hereby incorporated by reference in its entirety.

### TECHNICAL FIELD

The present disclosure relates to a field of display technology, and in particular to a display panel, a method of manufacturing a display panel, and a display device.

### BACKGROUND

In practical applications of a display product, it is needed to enable a peeping prevention mode in some privacy scenarios and enable a share mode in some public scenarios, which requires a display screen to have a function of switching between the peeping prevention mode and the share mode easily. For example, when viewing information using a mobile phone in public, it is possible to switch a display screen of the mobile phone to the peeping prevention mode in a case of showing a payment code or entering a password, and switch the display screen of the mobile phone to the share mode in other cases. In addition, for example, when using an in-car application display screen, it is possible to switch the display screen to the peeping prevention mode in a case that a front-seat passenger is watching entertainment information, and switch the display screen to the share mode in other cases.

How to optimize a display brightness and a viewing angle range in the share mode and the peeping prevention mode is one of important research topics for researchers in the field.

The above information disclosed in this section is merely for understanding of the background of technical concepts of the present disclosure. Therefore, the above information may contain information that does not constitute a related art.

### SUMMARY

In an aspect, a display panel is provided, including: a base substrate; a plurality of sub-pixels on the base substrate, where the plurality of sub-pixels are arranged in an array in a first direction and a second direction intersecting with the first direction, the plurality of sub-pixels include a plurality of sharing sub-pixels and a plurality of peeping prevention sub-pixels, and the peeping prevention sub-pixel includes a peeping prevention pixel opening; a light shielding layer on the base substrate, where the light shielding layer defines a plurality of opening regions, and an orthographic projection of the opening region on the base substrate at least partially overlaps with an orthographic projection of at least one peeping prevention pixel opening on the base substrate; and a lens structure on a side of the light shielding layer away from the base substrate, where an orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.

According to some exemplary embodiments, the display panel further includes: an encapsulation layer on the base substrate, where the encapsulation layer is configured to encapsulate the plurality of sharing sub-pixels and the plurality of peeping prevention sub-pixels; and a touch layer on a side of the encapsulation layer away from the base substrate, where at least one touch electrode is located in the touch layer, where the light shielding layer includes at least one of a first light shielding sub-layer, a second light shielding sub-layer or a third light shielding sub-layer, the first light shielding sub-layer is located between the touch layer and the lens structure, the second light shielding sub-layer is located between the touch layer and the encapsulation layer, and at least part of the touch layer is reused as the third light shielding sub-layer.

According to some exemplary embodiments, a maximum width of the orthographic projection of the peeping prevention pixel opening on the base substrate in the first direction is a first width, a maximum width of the orthographic projection of the lens structure on the base substrate in the first direction is a second width, and a ratio of the first width to the second width is less than or equal to 0.6.

According to some exemplary embodiments, the light shielding layer includes a first light shielding sub-layer, and the lens structure is in direct contact with at least part of the first light shielding sub-layer; or the light shielding layer includes a first light shielding sub-layer, the display panel further includes a first covering layer between the first light shielding sub-layer and the lens structure, and a surface of the lens structure close to the base substrate is spaced apart from a surface of the first light shielding sub-layer away from the base substrate.

According to some exemplary embodiments, the light-shielding layer includes a third light shielding sub-layer, and the lens structure is in direct contact with at least part of the third light shielding sub-layer; or the light shielding layer includes a third light shielding sub-layer, the display panel further includes a third covering layer between the third light shielding sub-layer and the lens structure, and a surface of the lens structure close to the base substrate is spaced apart from a surface of the third light shielding sub-layer away from the base substrate.

According to some exemplary embodiments, a light emitting layer of the peeping prevention sub-pixel includes a first surface away from the base substrate, the lens structure includes a second surface close to the base substrate, the first surface is spaced apart from the second surface by a first spacing distance, and the first spacing distance is less than a sum of the first width and the second width.

According to some exemplary embodiments, the first light shielding sub-layer defines a plurality of first opening regions, and an orthographic projection of a boundary of the peeping prevention pixel opening on the base substrate is surrounded by an orthographic projection of a boundary of a corresponding first opening region on the base substrate; or the orthographic projection of the peeping prevention pixel opening on the base substrate at least partially overlaps with an orthographic projection of the first light shielding sub-layer on the base substrate.

According to some exemplary embodiments, the second light shielding sub-layer defines a plurality of second opening regions, and an orthographic projection of a boundary of the peeping prevention pixel opening on the base substrate is surrounded by an orthographic projection of a boundary of a corresponding second opening region on the base substrate; or the orthographic projection of the peeping prevention pixel opening on the base substrate at least partially overlaps with an orthographic projection of the second light shielding sub-layer on the base substrate.

According to some exemplary embodiments, an orthographic projection of a first light shielding sub-layer corresponding to a peeping prevention pixel opening on the base substrate completely overlaps with an orthographic projection of a second light shielding sub-layer corresponding to the same peeping prevention pixel opening on the base substrate; or an orthographic projection of a first light shielding sub-layer corresponding to a peeping prevention pixel opening on the base substrate falls within an orthographic projection of a second light shielding sub-layer corresponding to the same peeping prevention pixel opening on the base substrate.

According to some exemplary embodiments, the third light shielding sub-layer defines a plurality of third opening regions, and an orthographic projection of the third opening region on the base substrate at least partially overlaps with an orthographic projection of the corresponding lens structure on the base substrate.

According to some exemplary embodiments, an orthographic projection of a third light shielding sub-layer corresponding to a peeping prevention pixel opening on the base substrate completely overlaps with an orthographic projection of a second light shielding sub-layer corresponding to the same peeping prevention pixel opening on the base substrate; or an orthographic projection of a third light shielding sub-layer corresponding to a peeping prevention pixel opening on the base substrate falls within an orthographic projection of a second light shielding sub-layer corresponding to the same peeping prevention pixel opening on the base substrate.

According to some exemplary embodiments, the first light shielding sub-layer has a first thickness, the encapsulation layer has a fourth thickness, and a ratio of the first thickness to the fourth thickness is greater than or equal to 0.05 and less than or equal to 0.5; and/or the second light shielding layer has a second thickness, the encapsulation layer has a fourth thickness, and a ratio of the second thickness to the fourth thickness is greater than or equal to 0.05 and less than or equal to 0.5.

According to some exemplary embodiments, the second light shielding sub-layer is made of a metal material having a reflectivity greater than or equal to 20%.

According to some exemplary embodiments, the second light shielding sub-layer has a second thickness, the encapsulation layer has a fourth thickness, and a ratio of the second thickness to the fourth thickness is greater than or equal to 0.005 and less than or equal to 0.5.

According to some exemplary embodiments, the third light shielding sub-layer has a third thickness, and a ratio of the third thickness to the fourth thickness is greater than or equal to 0.005 and less than or equal to 0.5.

According to some exemplary embodiments, the first light shielding sub-layer includes a third surface close to the base substrate, the first surface is spaced apart from the third surface by a third spacing distance, and the third spacing distance is less than or equal to the first spacing distance; and/or the second light shielding sub-layer includes a fourth surface close to the base substrate, the first surface is spaced apart from the fourth surface by a fourth spacing distance, and a ratio of the fourth spacing distance to the first width is greater than or equal to 1 and less than or equal to 2.

According to some exemplary embodiments, a ratio of the fourth spacing distance to the third spacing distance is greater than or equal to 0.2 and less than or equal to 0.85.

According to some exemplary embodiments, the touch layer includes a plurality of touch sub-lines between the plurality of peeping prevention sub-pixels, at least part of the plurality of touch sub-lines are configured to provide touch signals for corresponding peeping prevention sub-pixels, an orthographic projection of at least part of the touch sub-lines on the base substrate have a third width in the first direction, and the third width is less than the first width.

According to some exemplary embodiments, the third light shielding sub-layer includes a plurality of third light shielding sub-portions defining the third opening region, and an orthographic projection of the third light shielding sub-portion on the base substrate at least partially overlaps with the orthographic projection of the lens structure on the base substrate.

According to some exemplary embodiments, an orthographic projection of at least part of the third light shielding sub-portions on the base substrate has a fourth width in the first direction, and a ratio of the fourth width to the second width is greater than or equal to 0.2 and less than or equal to 0.8.

According to some exemplary embodiments, the display panel further includes a fourth covering layer on a side of the lens structure away from the base substrate, where a refractive index of a material in the fourth covering layer is less than a refractive index of a material in the lens structure.

According to some exemplary embodiments, a refractive index of a material in the first covering layer is less than a refractive index of a material in the lens structure; and/or a refractive index of a material in the third covering layer is less than the refractive index of the material in the lens structure.

According to some exemplary embodiments, the first spacing distance is less than twice the fourth thickness.

According to some exemplary embodiments, the plurality of sharing sub-pixels are divided into a plurality of sharing pixel units, and the plurality of peeping prevention sub-pixels are divided into a plurality of peeping prevention pixel units; the plurality of sharing pixel units are divided into a plurality of sharing pixel unit rows, the plurality of peeping prevention pixel units are divided into a plurality of peeping prevention pixel unit rows, and the sharing pixel unit rows and the peeping prevention pixel unit rows are arranged alternately.

According to some exemplary embodiments, the display panel includes a plurality of sharing pixel units, and the sharing pixel unit includes a plurality of first sub-pixels, a single second sub-pixel and a plurality of third sub-pixels; the display panel further includes a plurality of peeping prevention pixel units, and the peeping prevention pixel unit includes a plurality of fourth sub-pixels, a plurality of fifth sub-pixels and a plurality of sixth sub-pixels, and the sharing pixel unit and the peeping prevention pixel unit are arranged correspondingly.

According to some exemplary embodiments, the plurality of first sub-pixels and the plurality of fourth sub-pixels are configured to emit light of the same color, and the plurality of fourth sub-pixels are located in three side regions adjacent to the plurality of first sub-pixels; and/or the second sub-pixel and the plurality of fifth sub-pixels are configured to emit light of the same color, and the plurality of fifth sub-pixels are located in a side region adjacent to the second sub-pixel; and/or the plurality of third sub-pixels and the plurality of sixth sub-pixels are configured to emit light of the same color, the plurality of sixth sub-pixels are located in two side regions adjacent to the plurality of third sub-pixels, and the two side regions are located on opposite sides of the third sub-pixels.

In another aspect, a display device is provided, including the display panel described above.

In another aspect, a method of manufacturing a display panel is provided, including: forming a plurality of sub-pixels on a base substrate, where the plurality of sub-pixels are arranged on the base substrate in an array in a first direction and a second direction intersecting with the first direction, the plurality of sub-pixels include a plurality of sharing sub-pixels and a plurality of peeping prevention sub-pixels, and the peeping prevention sub-pixel includes a peeping prevention pixel opening; forming a light shielding layer on a side of the plurality of sub-pixels away from the base substrate, where the light shielding layer defines a plurality of opening regions, and an orthographic projection of the opening region on the base substrate at least partially overlaps with an orthographic projection of at least one peeping prevention pixel opening on the base substrate; and forming a lens structure on a side of the light shielding layer away from the base substrate, where an orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.

### BRIEF DESCRIPTION OF THE DRAWINGS

The above contents and other objectives, features and advantages of the present disclosure will be more apparent through the following descriptions of the embodiments of the present disclosure with reference to the accompanying drawings. In the accompanying drawings:

FIG. 1 shows a schematic diagram of a partial pixel arrangement of a display panel according to some embodiments of the present disclosure;

FIG. 2 shows a structure of a portion of the display panel according to some embodiments of the present disclosure;

FIG. 3 shows a schematic partial cross-sectional view of a display panel according to some embodiments of the present disclosure, taken along line AA′ in FIG. 2; FIG. 4 shows a comparison diagram of a light output effect of display panels with/without a lens structure in FIG. 3;

FIG. 5 shows a schematic partial cross-sectional view of a display panel according to other embodiments of the present disclosure, taken along line AA′ in FIG. 2; FIG. 6 shows a comparison diagram of a light output effect of display panels with/without a lens structure in FIG. 5;

FIG. 7 shows a schematic partial cross-sectional view of a display panel according to other embodiments of the present disclosure, taken along line AA′ in FIG. 2; FIG. 8 shows a comparison diagram of a light output effect of display panels with/without a lens structure in FIG. 7;

FIG. 9 shows a schematic partial cross-sectional view of a display panel according to other embodiments of the present disclosure, taken along line AA′ in FIG. 2; FIG. 10 shows a comparison diagram of a light output effect of display panels with/without a lens structure in FIG. 9;

FIG. 11 shows a schematic partial plan view of a touch layer according to the exemplary embodiments of the present disclosure;

FIG. 12 shows a schematic partial plan view of a touch layer according to the exemplary embodiments of the present disclosure;

FIG. 13 shows a schematic partial cross-sectional view of a display panel according to other embodiments of the present disclosure, taken along line AA′in FIG. 2; FIG. 14 shows a comparison diagram of a light output effect of display panels with/without a lens structure in FIG. 13;

FIG. 15 shows a schematic partial cross-sectional view of a display panel according to other embodiments of the present disclosure, taken along line AA′ in FIG. 2; FIG. 16 shows a comparison diagram of a light output effect of display panels with/without a lens structure in FIG. 15;

FIG. 17 shows a schematic partial cross-sectional view of a display panel according to other embodiments of the present disclosure, taken along line AA′ in FIG. 2;

FIG. 18 shows a schematic partial cross-sectional view of a display panel according to other embodiments of the present disclosure, taken along line AA′ in FIG. 2;

FIG. 19 shows a schematic partial cross-sectional view of a display panel according to other embodiments of the present disclosure, taken along line AA′ in FIG. 2; FIG. 20 shows a schematic partial cross-sectional view of a display panel according to other embodiments of the present disclosure, taken along line AA′ in FIG. 2;

FIG. 21 shows a structure of a portion of the display panel according to some embodiments of the present disclosure;

FIG. 22 shows a schematic partial cross-sectional view of a display panel according to other embodiments of the present disclosure, taken along line BB′ in FIG. 21;

FIG. 23 shows a schematic structural diagram of a display device according to some embodiments of the present disclosure; and

FIG. 24 shows a flowchart of a method of manufacturing a display panel according to some embodiments of the present disclosure.

It should be noted that, for the purpose of clarity, in the accompanying drawings used to describe the embodiments of the present disclosure, sizes of layers, structures or regions may be enlarged or reduced, that is, the accompanying drawings are not drawn to an actual scale.

### DETAILED DESCRIPTION OF EMBODIMENTS

In order to make objectives, technical solutions and advantages of the embodiments of the present disclosure clearer, technical solutions of the embodiments of the present disclosure will be clearly and completely described below with reference to the accompanying drawings. Obviously, the described embodiments are merely some embodiments rather than all embodiments of the present disclosure. Based on the described embodiments of the present disclosure, all additional embodiments obtained by those ordinary skilled in the art without carrying out inventive effort fall within the scope of protection of the present disclosure.

It should be noted that in the accompanying drawings, for clarity and/or description purposes, a size and relative size of an element may be enlarged. Accordingly, the size and relative size of each element need not to be limited to those shown in the figures. In the specification and the accompanying drawings, the same or similar reference numerals represent the same or similar components.

Unless otherwise defined, the technical or scientific terms used in embodiments of the present disclosure should have the usual meanings understood by those skilled in the art. The words “first”, “second” and the like used in the present disclosure do not indicate any order, quantity or importance, but are merely used to distinguish different composition parts. The word “including”, “containing” or the like means that an element or object preceding that word includes elements or objects listed after that word and their equivalents, but does not exclude other elements or objects.

Herein, unless otherwise specified, directional terms such as “upper”, “lower”, “left”, “right”, “inside”, “outside”, etc. are used to indicate orientations or positional relationships shown based on the accompanying drawings, which is intended to facilitate the descriptions of the present disclosure and not to indicate or imply that the device, element or component referred to must have a specific orientation or must be constructed or operated in a specific orientation. It should be understood that when an absolute position of a described object changes, the relative positional relationships indicated by those terms may also change accordingly. Therefore, those directional terms may not be understood as limitations to the present disclosure.

It should be noted that the expression “the same layer” herein refers to a layer structure that is formed by firstly forming, using a same film forming process, a film layer used to form a specific pattern, and then patterning, using one-time patterning process, the film layer with a same mask. Depending on different specific patterns, the one-time patterning process may include a plurality of exposure, development or etching processes, and the specific pattern in the formed layer structure may be continuous or discontinuous. That is, a plurality of elements, components, structures and/or portions located in the “same layer” are made of the same material and formed by the same patterning process. Generally, a plurality of elements, components, structures and/or portions located in the “same layer” have substantially the same thickness.

Those skilled in the art should understand that, unless otherwise specified, the expression “height” or “thickness” herein refers to a size in a direction perpendicular to a surface of each film layer provided on the display substrate, that is, a size in a light emitting direction of the display substrate, or called a size in a normal direction of the display device.

Herein, the directional expressions “first direction” and “second direction” are used to describe different directions along a pixel unit, e.g., a longitudinal direction and a transverse direction of the pixel unit, or a row direction and a column direction of an arrangement of sub-pixels. It should be understood that such expressions are merely exemplary descriptions and not limitations to the present disclosure.

In the present disclosure, “about” means that a numerical value within a process and measurement error range is allowed, without strictly defining the boundaries.

In the related art, display panels with peeping prevention functions are widely used in various fields. For example, AMOLED (Active Matrix Organic Light Emitting Diode) display panels are typically used as in-car display panels. When a vehicle is in a driving state, the display panel needs to be switched to a peeping prevention state to reduce visual interference to a user, prevent a display information displayed on the display panel from being acquired by a user in a driver position, and improve a user concentration in driving. When the vehicle is in a parking state, the display panel may be switched to a share state, so that the display information displayed on the display panel may be acquired by the user in time.

In order to meet user needs for peeping prevention of a display device, there are a variety of peeping prevention technologies for display panels on the market. For example, it is possible to add a layer of peeping prevention film on a surface of the display panel. However, such peeping prevention technology may not change a field of view angle of the display panel according to the user needs, and has a low flexibility. In some peeping prevention technologies, the display panel is partitioned for sharing sub-pixels and for peeping prevention sub-pixels and may be switched between different display states according to actual needs, that is, when a peeping prevention mode is enabled, a display information may not be acquired by a user outside a light output range of the peeping prevention sub-pixels of the display panel, while when the display panel is switched to a share mode, the field of view angle of the display panel may change so that the display information may be acquired by a user outside the light output range of the peeping prevention sub-pixels and within a light output range of the sharing sub-pixels of the display panel. However, because the display panel includes both sharing sub-pixels and peeping prevention sub-pixels, the outgoing light illuminated by the display panel in different display states has relatively low brightness, so that an overall light efficiency of the display panel decreases, which affects an overall appearance and visual experience of the display panel.

Some exemplary embodiments of the present disclosure provide a display panel, including: a base substrate; a plurality of sub-pixels on the base substrate, where the plurality of sub-pixels are arranged in an array in a first direction and a second direction intersecting with the first direction, the plurality of sub-pixels include a plurality of sharing sub-pixels and a plurality of peeping prevention sub-pixels, and the peeping prevention sub-pixel includes a peeping prevention pixel opening; a light shielding layer on the base substrate, where the light shielding layer defines a plurality of opening regions, and an orthographic projection of the opening region on the base substrate at least partially overlaps with an orthographic projection of at least one peeping prevention pixel opening on the base substrate; a lens structure on a side of the light shielding layer away from the base substrate, where an orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.

Through a partition design of the peeping prevention sub-pixels and the sharing sub-pixels, the light shielding layer and the lens structure provided in the region where the peeping prevention sub-pixels are located may effectively reduce the viewing angle range in the peeping prevention mode and increase the display brightness in the peeping prevention mode, so that a better display effect may be achieved.

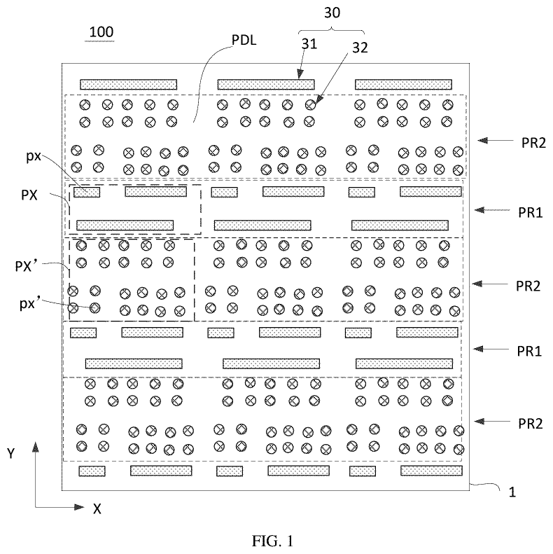

FIG. 1 shows a schematic diagram of a partial pixel arrangement of a display panel according to some embodiments of the present disclosure.

Referring to FIG. 1, in some embodiments, a display panel 100 includes a base substrate 1 and a plurality of sub-pixels on the base substrate 1, and the plurality of sub-pixels include a plurality of sharing sub-pixels px and a plurality of peeping prevention sub-pixels px′. The plurality of sub-pixels are arranged on the base substrate 1 in an array in a first direction X and a second direction Y, and the first direction X intersects with the second direction Y.

Exemplarily, the display panel 100 may include a plurality of sharing pixel unit rows PR1 and a plurality of peeping prevention pixel unit rows PR2.

Exemplarily, the sharing pixel unit row PR1 may include a plurality of sharing pixel units PX, and the peeping prevention pixel unit row PR2 may include a plurality of peeping prevention pixel units PX′.

Exemplarily, the plurality of sharing pixel units PX may include a plurality of sharing sub-pixels px, and the plurality of peeping prevention pixel units PX′ may include a plurality of peeping prevention sub-pixels px′.

Exemplarily, the sharing pixel unit rows PR1 and the peeping prevention pixel unit rows PR2 are arranged alternately.

In some embodiments, each of the plurality of sharing pixel unit rows PR1 includes a plurality of sharing sub-pixels px arranged sequentially, and each of the plurality of peeping prevention pixel unit rows PR2 includes a plurality of peeping prevention sub-pixels px′ arranged sequentially. The sub-pixels may be spaced apart by a pixel definition layer PDL. The pixel definition layer forms a plurality of openings, i.e., pixel openings 30, and a light emitting layer of the sub-pixel is located in the pixel opening 30, so that corresponding light emitting shape and light emitting area may be defined. For example, the sharing sub-pixel px includes a sharing pixel opening 31, and the peeping prevention sub-pixel px′ includes a peeping prevention pixel opening 32.

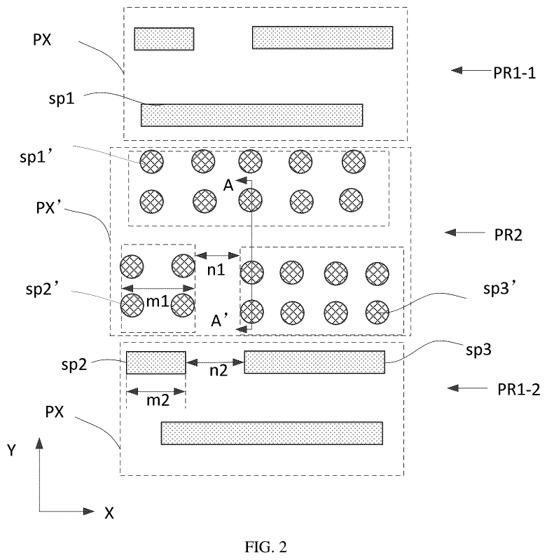

FIG. 2 shows a structure of a portion of the display panel according to some embodiments of the present disclosure.

Exemplarily, referring to FIG. 1 and FIG. 2, in some embodiments, each of the plurality of sharing pixel units PX includes a first sub-pixel sp1, a second sub-pixel sp2, and a third sub-pixel sp3.

In some embodiments, each of the plurality of peeping prevention pixel units PX′ includes one or more fourth sub-pixels sp1′, one or more fifth sub-pixels sp2′, and one or more sixth sub-pixels sp3′. In an example shown in FIG. 1 and FIG. 2, each peeping prevention pixel unit PX′ includes a plurality of fourth sub-pixels sp1′ (e.g., ten fourth sub-pixels sp1′), a plurality of fifth sub-pixels (e.g., four fifth sub-pixels sp2′), and a plurality of sixth sub-pixels (e.g., eight sixth sub-pixels sp3′).

In some examples, at least part of the peeping prevention pixel units PX′ include a single fourth sub-pixel, a single fifth sub-pixel, and a single sixth sub-pixel.

In some examples, at least part of the peeping prevention pixel units PX′ include a plurality of fourth sub-pixels, a plurality of fifth sub-pixels, and a single sixth sub-pixel.

In some examples, at least part of the peeping prevention pixel units PX′ include a single fourth sub-pixel, a plurality of fifth sub-pixels, and a plurality of sixth sub-pixels.

In some examples, at least part of the peeping prevention pixel units PX′ include a plurality of fourth sub-pixels, a single fifth sub-pixel, and a plurality of sixth sub-pixels.

In some embodiments, the first sub-pixel sp1 and the plurality of fourth sub-pixels sp1′ are sub-pixels having a first color (e.g., green). In some embodiments, the second sub-pixel sp2 and the plurality of fifth sub-pixels sp2′ are sub-pixels having a second color (e.g., red). In some embodiments, the third sub-pixel sp3 and the plurality of sixth sub-pixels are sub-pixels having a third color (e.g., blue). A sharing sub-pixel px and adjacent peeping prevention sub-pixels px′ have the same color, that is, the light emitting layer of the sharing sub-pixel px has the same color as the light emitting layer of the adjacent peeping prevention sub-pixels px′, which may reduce an interference and mixing between the sharing sub-pixel px and the peeping prevention sub-pixels px′, and avoid a color shift or uneven brightness in a display process of the display panel.

In some embodiments, an anode included in the peeping prevention sub-pixel and an anode included in the sharing sub-pixel may be independent of each other. The peeping prevention sub-pixel and the sharing sub-pixel may share a light emitting layer, that is, the light emitting layer of the peeping prevention sub-pixel and the light emitting layer of the sharing sub-pixel may be formed as an integrated structure. The peeping prevention sub-pixel and the sharing sub-pixel may share a cathode layer.

In some embodiments, the display panel includes an integral anode configured to provide a power signal to a plurality of fourth sub-pixels sp1′ in each peeping prevention pixel unit PX′. In some embodiments, the display panel includes an integral anode configured to provide a power signal to a plurality of fifth sub-pixels sp2′ in each peeping prevention pixel unit PX′. In some embodiments, the display panel includes an integral anode configured to provide a power signal to a plurality of sixth sub-pixels sp3′ in each peeping prevention pixel unit PX′.

In some examples, the display panel includes a plurality of anodes that are configured to independently provide power signals to a plurality of fourth sub-pixel sp1′ in each peeping prevention pixel unit PX′.

In some examples, the display panel includes a plurality of anodes that are configured to independently provide power signals to a plurality of fifth sub-pixels sp2′ in each peeping prevention pixel unit PX′.

In some examples, the display panel includes a plurality of anodes that are configured to independently provide power signals to a plurality of sixth sub-pixels sp3′ in each peeping prevention pixel unit PX′.

In some embodiments, the display panel includes an integral cathode, which is used for a plurality of fourth sub-pixels sp1′ in each peeping prevention pixel unit PX′ and a first sub-pixel sp1 in a sharing pixel unit PX in a first adjacent sharing pixel unit row PR1-1. In some embodiments, the display panel includes an integral light emitting layer, which is used for a plurality of fourth sub-pixels sp1′ in each peeping prevention pixel unit PX′ and a first sub-pixel sp1 in the sharing pixel unit PX in the first adjacent sharing pixel unit row PR1-1. In some embodiments, the display panel includes two independent anodes, one is used for a plurality of fourth sub-pixels sp1′ in each peep prevention pixel unit PX′, and the other is used for the first sub-pixel sp1 in the sharing pixel unit PX in the first adjacent sharing pixel unit row PR1-1. The two independent anodes are independently controlled and configured to receive independent power signals.

In some embodiments, the display panel includes an integral cathode, which is used for a plurality of fifth sub-pixels sp2′ in each peeping prevention pixel unit PX′ and a second sub-pixel sp2 in a sharing pixel unit PX in a second adjacent sharing pixel unit row PR1-2. The peeping prevention sub-pixel is located in a peeping prevention pixel unit row PR2 that separates the first adjacent sharing pixel unit row PR1-1 and the second adjacent sharing pixel unit row PR1-2. In some embodiments, the display panel includes an integral light emitting layer, which is used for a plurality of fifth sub-pixels sp2′ in each peeping prevention pixel unit PX′ and a second sub-pixel sp2 in the sharing pixel unit PX in the second adjacent sharing pixel unit row PR1-2. In some embodiments, the display panel includes two independent anodes, one is used for a plurality of fifth sub-pixels sp2′ in each peep prevention pixel unit PX′, and the other is used for the second sub-pixel sp2 in the sharing pixel unit PX in the second adjacent sharing pixel unit row PR1-2. The two independent anodes are independently controlled and configured to receive independent power signals.

In some embodiments, the display panel includes an integral cathode, which is used for a plurality of sixth sub-pixels sp3′ in each peeping prevention pixel unit PX′ and a third sub-pixel sp3 in a sharing pixel unit PX in a second adjacent sharing pixel unit row PR1-2. In some embodiments, the display panel includes an integral light emitting layer, which is used for a plurality of sixth sub-pixels sp3′ in each peeping prevention pixel unit PX′ and a third sub-pixel sp3 in the sharing pixel unit PX in the second adjacent sharing pixel unit row PR1-2. In some embodiments, the display panel includes two independent anodes, one is used for a plurality of sixth sub-pixels sp3′ in each peep prevention pixel unit PX′, and the other is used for the third sub-pixel sp3 in the sharing pixel unit PX in the second adjacent sharing pixel unit row PR1-2. The two independent anodes are independently controlled and configured to receive independent power signals.

In some embodiments, the display panel is configured to operate in a first mode, a second mode, or a third mode. In the first mode, the sharing sub-pixels in the plurality of sharing pixel unit rows PR1 and the peeping prevention sub-pixels in the plurality of peeping prevention pixel unit rows PR2 are configured to emit light. In the second mode, the peeping prevention sub-pixels in the plurality of peeping prevention pixel unit rows PR2 are configured to display an image (e.g., emit light), while the sharing sub-pixels in the plurality of sharing pixel unit rows PR1 are not configured to display an image (e.g., not configured to emit light). In some embodiments, the second mode is a peeping prevention mode (privacy mode). In the third mode, the peeping prevention sub-pixels in the plurality of peeping prevention pixel unit rows PR2 are not configured to display an image (e.g., not configured to emit light), while the sharing sub-pixels in the plurality of sharing pixel unit rows PR1 are configured to display an image (e.g., emit light).

It should be noted that in the above-mentioned embodiments, the number of sharing sub-pixels px, the number of peeping prevention sub-pixels px′, an opening area of a single sharing sub-pixel px, an opening area of a single peeping prevention sub-pixel px′ and other specification parameters may be selected and set according to a manufacturing process of the display panel. For example, the number of sharing sub-pixels px may be the same as or different from the number of peeping prevention sub-pixels px′, and/or the opening area of a single sharing sub-pixel px may be the same as or different from the opening area of a single peeping prevention sub-pixel px′, so that the display panel presents different display effects in the share mode and the peeping prevention mode. For example, for the sharing sub-pixels px and the peeping prevention sub-pixels px′ in the display panel, the number of sharing sub-pixels px may be less than the number of peeping prevention sub-pixels px′, and the opening area of a single sharing sub-pixel px may be different from the opening area of a single peeping prevention sub-pixel px′.

In some embodiments, each sharing pixel unit PX in the plurality of sharing pixel unit rows PR1 includes a first sub-pixel sp1, a second sub-pixel sp2, and a third sub-pixel sp3. Each peeping prevention pixel unit PX′ in the plurality of peeping prevention pixel unit rows PR2 includes a plurality of fourth sub-pixels sp1′, a plurality of fifth sub-pixels sp2′, and a plurality of sixth sub-pixels sp3′. The plurality of fourth sub-pixels sp1′ may include two fourth sub-pixels sp1′, the plurality of fifth sub-pixels sp2′ may include two fifth sub-pixels sp2′, and the plurality of sixth sub-pixels sp3′ may include two sixth sub-pixels sp3′.

In some examples, in each peeping prevention pixel unit PX′ in the plurality of peeping prevention pixel unit rows PR2, the number of sixth sub-pixels sp3′ is greater than or equal to the number of fifth sub-pixels sp2′, and each of the two is greater than the number of fourth sub-pixels sp1′. In each sharing pixel unit PX in the plurality of sharing pixel unit rows PR1, the number of first sub-pixels sp1, the number of second sub-pixels sp2 and the number of third sub-pixels sp3 are equal to each other.

In some examples, the plurality of fourth sub-pixels sp1′ may include two fourth sub-pixels sp1′, the plurality of fifth sub-pixels sp2′ may include four fifth sub-pixels sp2′, and the plurality of sixth sub-pixels sp3′ may include four sixth sub-pixels sp3′.

In some examples, the plurality of fourth sub-pixels sp1′ may include three fourth sub-pixels sp1′, the plurality of fifth sub-pixels sp2′ may include sixth fifth sub-pixels sp2′, and the plurality of sixth sub-pixels sp3′ may include nine sixth sub-pixels sp3′

In some examples, the plurality of fourth sub-pixels sp1′ may include three fourth sub-pixels sp1′, the plurality of fifth sub-pixels sp2′ may include nine fifth sub-pixels sp2′, and the plurality of sixth sub-pixels sp3′ may include nine sixth sub-pixels sp3′.

In general, the larger the area assigned to sub-pixels having the same color in a sub-pixel, the greater the number of sub-pixels having the same color in that sub-pixel. In some embodiments, a ratio of the number of the plurality of fourth sub-pixels sp1′, the number of the plurality of fifth sub-pixels sp2′ and the number of the plurality of sixth sub-pixels sp3′ ranges from 1 to 3, such as 1, 2 or 3.

In some embodiments, the peeping prevention sub-pixels having the same color may be the same or different in terms of shape and size. For example, the peeping prevention sub-pixels having the same color may have the same shape and size.

Exemplarily, the peeping prevention sub-pixels having different colors may be the same or different in terms of shape and size. For example, an area ratio of a single fourth sub-pixel sp1′ to a single fifth sub-pixel sp2′ ranges from 0.5 to 2.0. For example, an area ratio of a single fourth sub-pixel sp1′ to a single sixth sub-pixel sp3′ ranges from 0.5 to 2.0. For example, an area ratio of a single fifth sub-pixel sp2′ to a single sixth sub-pixel sp3′ ranges from 0.5 to 2.0.

In some embodiments, a total area A1 of the peeping prevention pixel openings of a plurality of peeping prevention sub-pixels having the same color in a peeping prevention pixel unit is less than or equal to a total area A2 of the pixel opening of the sharing sub-pixel having the same color in the corresponding sharing pixel unit. For example, a ratio of A1 to A2 is greater than or equal to 0.5 and less than or equal to 1. For example, the ratio of A1 to A2 may be equal to 4/6, or the ratio of A1 to A2 may be equal to 4/7. In some embodiments, the first sub-pixel sp1 and the fourth sub-pixel sp1′ are green sub-pixels, the second sub-pixel sp2 and the fifth sub-pixel sp2′ are red sub-pixels, and the third sub-pixel sp3 and the sixth sub-pixel sp3′ are blue sub-pixels. As shown in FIG. 2, for the sharing sub-pixels px in the same pixel region, the opening area of a single red second sub-pixel SP2 may be less than the opening area of a single blue third sub-pixel SP3, and the opening area of a single blue third sub-pixel sp3 may be less than the opening area of a single green first sub-pixel sp1; for the peeping prevention sub-pixels px′ in the same pixel region, the total opening area of the red fifth sub-pixels sp2′ may be less than the total opening area of the blue sixth sub-pixels sp3′, and the total opening area of the blue sixth sub-pixels sp3′ may be less than the total opening area of the green fourth sub-pixels sp1′, where the total opening area is equal to the product of the opening area of a single peeping prevention sub-pixel and the number of corresponding peeping prevention sub-pixels in the same pixel region. For example, in a pixel region in FIG. 2, four red fifth sub-pixels sp2′ are provided, and the total opening area of the red fifth sub-pixels sp2′ is equal to four times the opening area of a single red fifth sub-pixel sp2′.

In some embodiments, an opening shape of the sharing sub-pixel px is a strip, and adjacent sharing sub-pixels px extend in the same direction; and an opening shape of the peeping prevention sub-pixel px′ is a dot, but the present disclosure is not limited to this.

By setting the sharing sub-pixel px to a strip shape and extending the sharing sub-pixels px in each pixel region in the same direction, it is possible to increase the field of view angle of the sharing sub-pixel px in the extension direction and limit the field of view in a direction perpendicular to the extension direction of the sharing sub-pixel px, so that the display panel may share the display information in a fixed direction and avoid information leakage in other directions. By setting the peeping prevention sub-pixel px′ to a dot shape, the field of view angle of the display panel in different display states may remain unchanged to ensure a relatively uniform light output effect of the pixel regions, so that a clear and stable display information may be acquired by a user in the light output range of the peeping prevention sub-pixel px′.

In some embodiments, continuing to refer to FIG. 2, in a combination of a single peeping prevention pixel unit and a single sharing pixel unit, an orthographic projection of a plurality of peeping prevention sub-pixels having the same color on the base substrate has a maximum coverage width m1 in the first direction X, an orthographic projection of a sharing sub-pixel corresponding to the plurality of peeping prevention sub-pixels on the base substrate has a maximum coverage width m2 in the first direction X, and m2 is less than or equal to m1.

In some embodiments, continuing to refer to FIG. 2, in a combination of a single peeping prevention pixel unit and a single sharing pixel unit, a minimum spacing distance between the second sub-pixel sp2 and the third sub-pixel sp3 is n2, a minimum spacing distance between the plurality of fifth sub-pixels sp2′ and the plurality of sixth sub-pixels sp3′ is n1, and n2 is greater than or equal to n1.

It should be noted that in some embodiments of the present disclosure, both the sharing sub-pixels and the peeping prevention sub-pixels may adopt a pixel arrangement of S-stripe RGB, but the present disclosure is not limited to this. For example, the sharing sub-pixels and the peeping prevention sub-pixels may also adopt Delta RGB pixel arrangement, GGRB pixel arrangement, Blue Diamond pixel arrangement, Diamond pixel arrangement and other well-known pixel arrangements in the art.

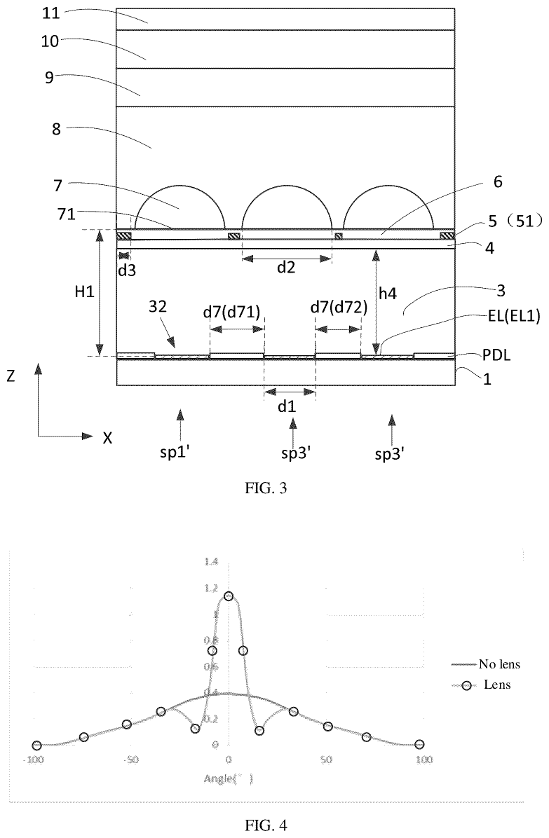

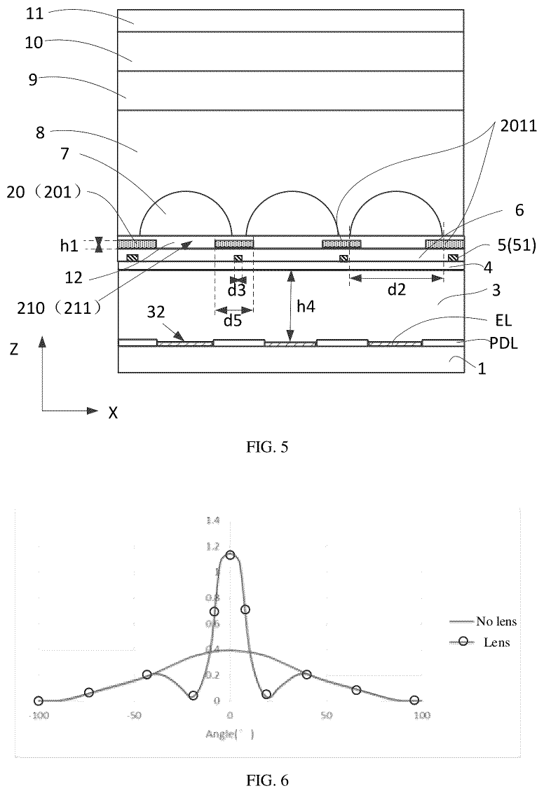

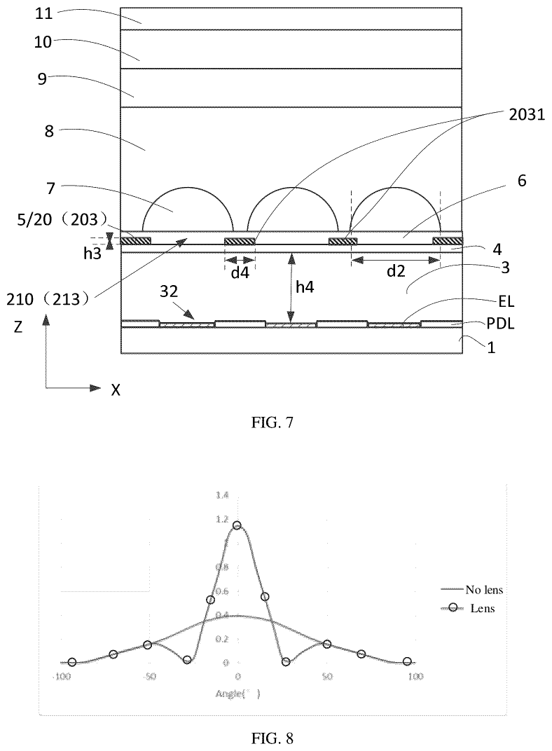

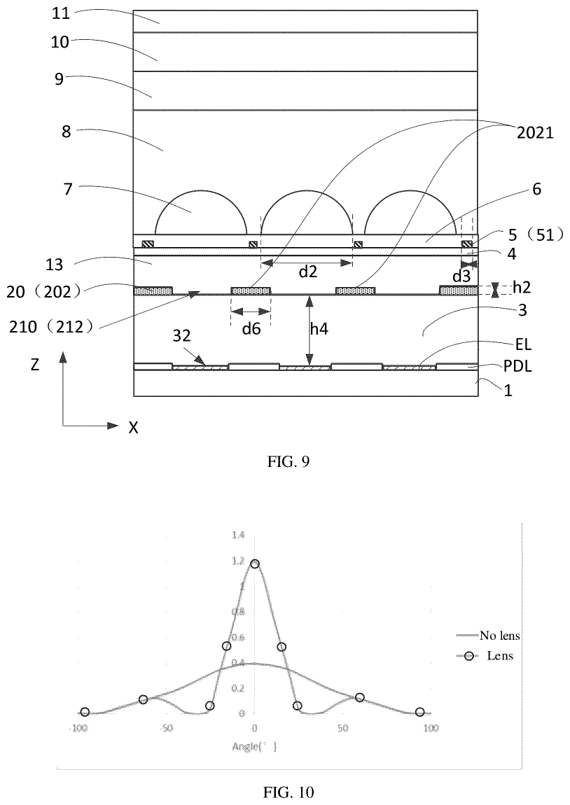

FIG. 3 shows a schematic partial cross-sectional view of a display panel according to some embodiments of the present disclosure, taken along line AA′ in FIG. 2; FIG. 4 shows a comparison diagram of a light output effect of display panels with/without a lens structure in FIG. 3; FIG. 5 shows a schematic partial cross-sectional view of a display panel according to other embodiments of the present disclosure, taken along line AA′ in FIG. 2; FIG. 6 shows a comparison diagram of a light output effect of display panels with/without a lens structure in FIG. 5; FIG. 7 shows a schematic partial cross-sectional view of a display panel according to other embodiments of the present disclosure, taken along line AA′ in FIG. 2; FIG. 8 shows a comparison diagram of a light output effect of display panels with/without a lens structure in FIG. 7; FIG. 9 shows a schematic partial cross-sectional view of a display panel according to other embodiments of the present disclosure, taken along line AA′ in FIG. 2; FIG. 10 shows a comparison diagram of a light output effect of display panels with/without a lens structure in FIG. 9.

Exemplarily, in some embodiments of the present disclosure, referring to FIG. 3, FIG. 5, FIG. 7 and FIG. 9, the display panel includes a base substrate 1 and a pixel definition layer PDL. The pixel definition layer PDL in a region where the peeping prevention sub-pixels are located defines a plurality of peeping prevention pixel openings 32. The display panel may further include a light shielding layer 20 on the base substrate 1. For example, the light shielding layer 20 may include at least one of a first light shielding sub-layer 201, a second light shielding sub-layer 202, or a third light shielding sub-layer 203. The light shielding layer defines a plurality of opening regions 210, which may include, for example, at least one of a first opening region 211, a second opening region 212, or a third opening region 213.

An orthographic projection of the opening region 210 on the base substrate 1 at least partially overlaps with an orthographic projection of at least one peeping prevention pixel opening 32 on the base substrate. By providing the light shielding layer, at least a majority of the light emitted by the peeping prevention sub-pixel may only be emitted from the opening region 210 to a light output side of the display panel, so that the display panel may achieve the peeping prevention mode through the peeping prevention sub-pixels.

Exemplarily, the display panel may further include a pixel driving circuit layer (not shown) between the pixel definition layer PDL and the base substrate 1, which is used to drive the sub-pixels to emit light. The pixel driving circuit layer may adopt various pixel driver designs known in the art, such as 3T1C, 7T1C, 7T2C, 8T2C, etc., which will not be described in detail here.

The display panel further includes a lens structure 7 on a side of the light shielding layer 20 away from the base substrate 1. An orthographic projection of at least one peeping prevention pixel opening 32 on the base substrate 1 falls within an orthographic projection of the lens structure 7 on the base substrate 1. The orthographic projection of the lens structure 7 on the base substrate at least partially overlaps with an orthographic projection of at least one opening region 210 on the base substrate 1. By correspondingly providing the lens structure 7 above the peeping prevention pixel opening, it is possible to better increase a light output efficiency of the peeping prevention sub-pixels and further improve the display effect of the display panel in the peeping prevention mode.

The display panel may further include an encapsulation layer 3 on a side of the pixel definition layer PDL away from the base substrate. The encapsulation layer 3 is used to encapsulate the plurality of sub-pixels of the display substrate, such as encapsulating the plurality of sharing sub-pixels and the plurality of peeping prevention sub-pixels. That is, in some embodiments of the present disclosure, the sharing sub-pixels and the peeping prevention sub-pixels may share the encapsulation layer.

The display panel may further include a touch layer 5 on a side of the encapsulation layer 3 away from the base substrate 1, and at least one touch electrode is located in the touch layer. Through the design of the touch layer, the display panel may achieve a touch control.

Exemplarily, a second protective layer 4 may be further provided between the encapsulation layer 3 and the touch layer 5. The second protective layer 4 may be an insulation layer.

Exemplarily, in some embodiments of the present disclosure, referring to FIG. 5, the first light shielding sub-layer 201 is located between the touch layer 5 and the lens structure 7. Exemplarily, referring to FIG. 9, the second light shielding sub-layer 202 is located between the touch layer 5 and the encapsulation layer 3. Exemplarily, referring to FIG. 7, at least part of the touch layer 5 is reused as the third light shielding sub-layer 203.

The first light shielding sub-layer 201, the second light shielding sub-layer 202 and the third light shielding sub-layer 203 may be separately used as light shielding layers, or may be designed in combination to achieve a better peeping prevention display effect. For example, the first light shielding sub-layer 201 and the second light shielding sub-layer 202 may be designed in combination, or the second light shielding sub-layer 202 and the third light shielding sub-layer 203 may be designed in combination, or the first light shielding sub-layer 201 and the third light shielding sub-layer 203 may be designed in combination, or the first light shielding sub-layer 201, the second light shielding sub-layer 202 and the third light shielding sub-layer 203 may be designed in combination.

Exemplarily, in some embodiments of the present disclosure, referring to FIG. 3, a maximum width of the orthographic projection of the peeping prevention pixel opening 32 on the base substrate in the first direction X is a first width d1, a maximum width of the orthographic projection of the lens structure 7 on the base substrate in the first direction X is a second width d2, and a ratio of the first width d1 to the second width d2 is less than or equal to 0.6. For example, the first width d1 may be less than or equal to 6 microns, and the second width d2 may range from 6 microns to 40 microns, but the present disclosure is not limited to this. For example, the first width d1 may be 6 microns, and the second width d2 may be 11 microns. By designing a small light emitting area and a relatively large lens structure in the peeping prevention sub-pixel region, it is possible to reduce the viewing angle of the peeping prevention region, which helps improve the peeping prevention effect. Furthermore, it is also possible to improve the display brightness of the peeping prevention region, which helps improve the overall display effect of the display panel.

Exemplarily, referring to FIG. 2 and FIG. 3, in some embodiments of the present disclosure, a spacing distance d7 is formed between adjacent peeping prevention pixel openings, and the spacing distances d7 between different peeping prevention pixel openings may be the same or different. For example, for the peeping prevention sub-pixels that emit light of the same color, a spacing distance d72 is formed between the peeping prevention pixel openings. For example, referring to FIG. 3, the spacing distance d72 is formed between two peeping prevention pixel openings corresponding to two sixth sub-pixels sp3′. For two adjacent peeping prevention sub-pixels that emit light of different colors, a spacing distance d71 is formed between the peeping prevention pixel openings. For example, the spacing distance d71 is formed between a peeping prevention pixel opening corresponding to a fourth sub-pixel sp1′ and a peeping prevention pixel opening corresponding to an adjacent sixth sub-pixel sp3′. Exemplarily, d72 is less than d71.

Exemplarily, in some embodiments of the present disclosure, referring to FIG. 3, the light emitting layer EL of the peeping prevention sub-pixel includes a first surface EL1 away from the base substrate, and the lens structure 7 includes a second surface 71 close to the base substrate. The first surface EL1 is spaced apart from the second surface 71 by a first spacing distance H1. The first spacing distance H1 is less than a sum of the first width d1 and the second width d2. For example, the first spacing distance H1 may be 14 microns, the first width may be 6 microns, and the second width may be 11 microns.

Exemplarily, in some embodiments of the present disclosure, referring to FIG. 3, the pixel definition layer PDL may be made of a black material. The encapsulation layer 3 may adopt thin film encapsulation, such as inorganic/organic/inorganic three-layer or multi-layer structure. Exemplarily, the encapsulation layer has a fourth thickness h4, which ranges from 2 microns to 20 microns, such as 8 microns to 20 microns, but the present disclosure is not limited to this. The touch layer may consist of one or more layers of metal mesh. The touch layer includes a plurality of metal wires. Exemplarily, referring to FIG. 3, the touch layer 5 includes a plurality of touch sub-lines 51 between the plurality of peeping prevention sub-pixels. At least part of the plurality of touch sub-lines 51 are used to provide touch signals for corresponding peeping prevention sub-pixels. An orthographic projection of at least part of the touch sub-lines 51 on the base substrate has a third width d3 in the first direction, and the third width d3 is less than the first width d1. For example, the third width d3 may range from 2 microns to 4 microns, and the first width d1 may be 6 microns, but the present disclosure is not limited to this. In some embodiments, the plurality of touch sub-lines 51 in the touch layer 5 may have a small width and are used only for transmitting touch signals.

Lower surfaces of at least part of the plurality of metal wires close to the base substrate are blackened. Exemplarily, the blackened metal wires have a low light reflectivity of around 5%, so that stray light may be reduced. A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure ranges from 8 microns to 40 microns, but the present disclosure is not limited to this. The lens structure is made of a high refractive index material. For example, the material in the lens structure 7 may have a refractive index from 1.5 to 1.8, but the present disclosure is not limited to this. A material around the lens structure 7 is a low refractive index material. For example, the first protective layer 6 below the lens structure 7 in FIG. 3 is made of a low refractive index material, and the refractive index of the material in the lens structure 7 is greater than that of the material in the first protective layer 6. For example, the refractive index of the material in the first protective layer 6 ranges from 1.4 to 1.6, but the present disclosure is not limited to this.

The display panel may further include a fourth covering layer 8 on a side of the lens structure 7 away from the base substrate. The refractive index of the material in the fourth covering layer 8 is less than that of the material in the lens structure 7. For example, the material in the fourth covering layer 8 has a refractive index from 1.4 to 1.6, but the present disclosure is not limited to this.

By designing the refractive index of the material in the lens structure to be larger than that of the material around the lens structure, it is possible to improve a light concentration effect of the lens structure, which helps further improve the display brightness of the display panel in the peeping prevention mode.

Exemplarily, the display panel may further include an optical adhesive layer 9, a cover plate 10 and a hardened protective layer 11, which are located on the fourth covering layer 8.

Exemplarily, referring to FIG. 4, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 3 provided with the lens structure is greatly improved in the brightness of the peeping prevention pixel region in a front viewing angle range (for example, −20° to 20°, or −30° to 30°), for example, the brightness near the 0° viewing angle is increased by about 300%, which helps further improve the display effect of the display panel in the peeping prevention mode.

Exemplarily, in some embodiments of the present disclosure, referring to FIG. 5, the pixel definition layer PDL may be made of a black material. The encapsulation layer 3 may adopt thin film encapsulation, such as inorganic/organic/inorganic three-layer or multi-layer structure. Exemplarily, the encapsulation layer has a fourth thickness h4, which ranges from 2 microns to 20 microns, such as 8 microns to 20 microns, but the present disclosure is not limited to this. The touch layer may consist of one or more layers of metal mesh. The touch layer 5 includes a plurality of metal wires. For example, the touch layer 5 includes a plurality of touch sub-lines 51 between the plurality of peeping prevention sub-pixels. An orthographic projection of at least part of the touch sub-lines 51 on the base substrate has a third width d3 in the first direction, and the third width d3 ranges from 2 microns to 4 microns. Lower surfaces of at least part of the plurality of metal wires close to the base substrate are blackened. Exemplarily, the blackened metal wires have a low light reflectivity of around 5%, so that stray light may be reduced. A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure 7 ranges from 8 microns to 40 microns, but the present disclosure is not limited to this. The lens structure 7 is made of a high refractive index material. For example, the material in the lens structure 7 may have a refractive index from 1.5 to 1.8, but the present disclosure is not limited to this. A material around the lens structure 7 is a low refractive index material. The display panel may further include a fourth covering layer 8, an optical adhesive layer 9, a cover plate 10 and a hardened protective layer 11 on the lens structure 7, which will not be described in detail here.

Continuing to refer to FIG. 5, the light shielding layer may further include a first light shielding sub-layer 201 between the touch layer 5 and the lens structure 7.

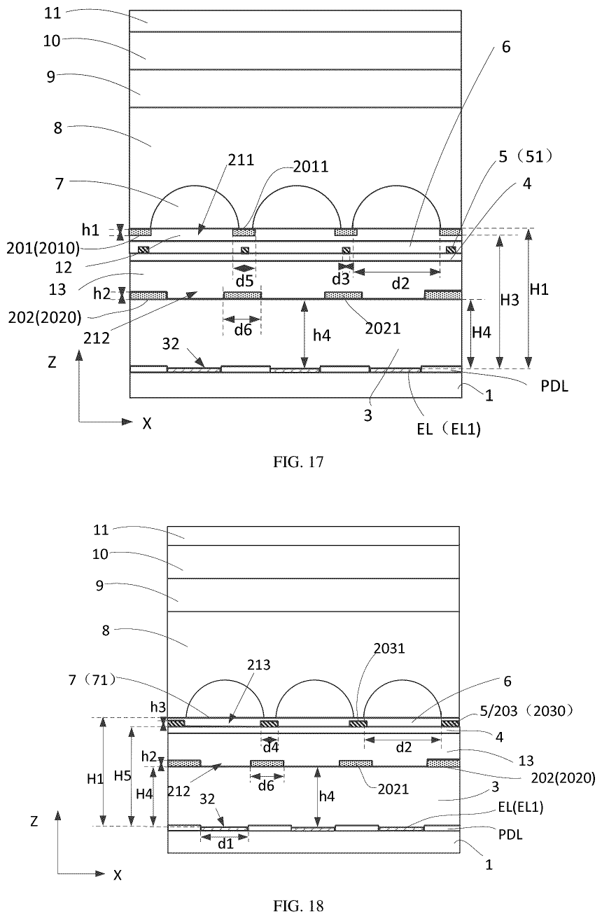

Exemplarily, referring to FIG. 17, the lens structure 7 may be in direct contact with at least part of the first light shielding sub-layer 201.

Exemplarily, referring to FIG. 5, a first covering layer 12 may be filled between the first light shielding sub-layer 201 and the lens structure 7. For example, the first covering layer may be an insulation layer. The first covering layer 12 may cover an upper surface of the first light shielding sub-layer 201, so that a surface of the lens structure 7 close to the base substrate is spaced apart from a surface of the first light shielding sub-layer 201 away from the base substrate, which means that the lens structure 7 is not in direct contact with the first light shielding sub-layer 201.

The first light shielding sub-layer 201 includes a plurality of first light shielding sub-portions 2011, and an orthographic projection of at least one first light shielding sub-portion 2011 on the base substrate has a fifth width d5 in the first direction. The fifth width d5 ranges from 4 microns to 20 microns, but the present disclosure is not limited to this.

Exemplarily, the first light shielding sub-layer 201 defines a plurality of first opening regions 211. An orthographic projection of a boundary of the peeping prevention pixel opening 32 on the base substrate is surrounded by an orthographic projection of a boundary of a corresponding first opening region 211 on the base substrate. Alternatively, an orthographic projection of the peeping prevention pixel opening 32 on the base substrate at least partially overlaps with an orthographic projection of the first light shielding sub-layer 201 on the base substrate. For example, a distance between the orthographic projection of the boundary of the peeping prevention pixel opening 32 on the base substrate and the orthographic projection of the boundary of the corresponding first opening region 211 on the base substrate ranges from −3 microns to 10 microns, or from −1 micron to 10 microns, such as 0 to 6 microns.

It should be noted that, when the above-mentioned distance is a positive value, it means that the orthographic projection of the boundary of the peeping prevention pixel opening 32 on the base substrate does not overlap with the orthographic projection of the first light shielding sub-layer 201 on the base substrate; and when the above-mentioned distance is a negative value, it means that the orthographic projection of the boundary of the peeping prevention pixel opening 32 on the base substrate overlaps with the orthographic projection of the first light shielding sub-layer 201 on the base substrate.

By providing the first light shielding sub-layer 201, at least a majority of the light emitted by the peeping prevention sub-pixel may only be emitted from the first opening region 210 to the light output side of the display panel, so that the display panel may achieve the peeping prevention mode through the peeping prevention sub-pixels.

Exemplarily, in some embodiments of the present disclosure, the first light shielding sub-layer 201 has a first thickness h1, and the encapsulation layer 3 has a fourth thickness h4. A ratio of the first thickness h1 to the fourth thickness h4 is greater than or equal to 0.05 and less than or equal to 0.5. For example, the first thickness h1 may range from 1 micron to 3 microns, and the fourth thickness h4 may range from 2 microns to 20 microns, such as from 8 microns to 20 microns.

Exemplarily, referring to FIG. 6, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 5 provided with the lens structure is greatly improved in the brightness of the peeping prevention pixel region in a front viewing angle range (for example, −20° to 20°, or −30° to 30°), for example, the brightness near the 0° viewing angle is increased by about 300%, which helps further improve the display effect of the display panel in the peeping prevention mode.

Exemplarily, in some embodiments of the present disclosure, referring to FIG. 7, the pixel definition layer PDL may be made of a black material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 8 microns to 20 microns, but the present disclosure is not limited to this. The touch layer 5 may consist of one or more layers of metal mesh. The touch layer 5 includes a plurality of metal wires. Lower surfaces of at least part of the plurality of metal wires close to the base substrate are blackened, so that stray light may be reduced. At least part of the plurality of metal wires are reused as the third light shielding sub-layer 203. The third light shielding sub-layer 203 defines a plurality of third opening regions 213, and an orthographic projection of the third opening region 213 on the base substrate at least partially overlaps with the orthographic projection of the corresponding lens structure 7 on the base substrate.

Exemplarily, continuing to refer to FIG. 7, the third light shielding sub-layer 203 may include a plurality of third light shielding sub-portions 2031. An orthographic projection of the third light shielding sub-portion 2031 on the base substrate defines the corresponding third opening region 213. An orthographic projection of the third light shielding sub-portion 2031 on the base substrate at least partially overlaps with the orthographic projection of the lens structure 7 on the base substrate.

Exemplarily, an orthographic projection of a boundary of the peeping prevention pixel opening 32 on the base substrate is surrounded by an orthographic projection of a boundary of a corresponding third opening region 213 on the base substrate. Alternatively, an orthographic projection of the peeping prevention pixel opening 32 on the base substrate at least partially overlaps with an orthographic projection of the third light shielding sub-layer 203 on the base substrate. For example, a distance between the orthographic projection of the boundary of the peeping prevention pixel opening 32 on the base substrate and the orthographic projection of the boundary of the corresponding third opening region 213 on the base substrate ranges from −3 microns to 10 microns, or from −1 micron to 10 microns, such as 0 to 6 microns.

It should be noted that, when the above-mentioned distance is a positive value, it means that the orthographic projection of the boundary of the peeping prevention pixel opening 32 on the base substrate does not overlap with the orthographic projection of the third light shielding sub-layer 203 on the base substrate; and when the above-mentioned distance is a negative value, it means that the orthographic projection of the boundary of the peeping prevention pixel opening 32 on the base substrate overlaps with the orthographic projection of the third light shielding sub-layer 203 on the base substrate.

A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure 7 ranges from 8 microns to 40 microns, but the present disclosure is not limited to this. The lens structure is made of a high refractive index material. For example, the material in the lens structure 7 may have a refractive index from 1.5 to 1.8, but the present disclosure is not limited to this. A material around the lens structure 7 is a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 7, an orthographic projection of at least part of the third light shielding sub-portions 2031 on the base substrate has a fourth width d4 in the first direction X. A ratio of the fourth width d4 to the second width d2 ranges from 0.2 to 0.8, such as about 0.5. For example, the fourth width d4 ranges from 4 microns to 20 microns, but the present disclosure is not limited to this.

By reusing at least part of the touch layer as the third light shielding sub-layer 203, it is avoided to form a third light shielding sub-layer 203 specially used for shielding light in the touch display panel, so that the number of film layers in the touch display panel is reduced, an internal structure of the touch display panel is optimized, and problems of complex structure, large product-thickness and high production cost of a display product having a function of switching between the peeping prevention mode and the screen information share mode may be solved.

Exemplarily, the first protective layer 6 may be used as a third covering layer so that a surface of the lens structure 7 close to the base substrate is spaced apart from a surface of the third light shielding sub-layer 203 away from the base substrate.

Exemplarily, the refractive index of the material in the third covering layer is less than that of the material in the lens structure, so that the lens structure has a better light concentration.

Exemplarily, in some embodiments of the present disclosure, the third light shielding sub-layer 203 has a third thickness h3. A ratio of the third thickness h3 to the fourth thickness h4 is greater than or equal to 0.005 and less than or equal to 0.5. For example, the third thickness h3 may range from 0.1 microns to 3 microns, and the fourth thickness h4 may range from 2 microns to 20 microns, such as 8 microns to 20 microns. By providing a thin third light shielding sub-layer 203, it is possible to increase a flatness of the film layer, which helps the formation of the lens structure above the light shielding layer.

Exemplarily, referring to FIG. 8, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 7 provided with the lens structure is greatly improved in the brightness of the peeping prevention pixel region in a front viewing angle range (for example, −20° to 20°, or −30° to 30°), for example, the brightness near the 0° viewing angle is increased by about 300%, which helps further improve the display effect of the display panel in the peeping prevention mode.

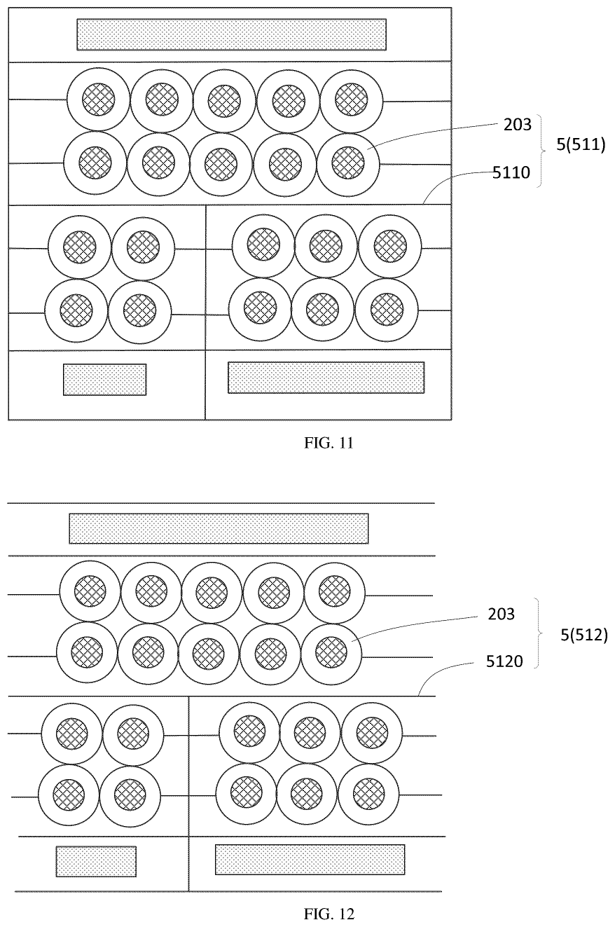

FIG. 11 shows a schematic partial plan view of a touch layer according to the exemplary embodiments of the present disclosure; FIG. 12 shows a schematic partial plan view of a touch layer according to the exemplary embodiments of the present disclosure.

Referring to FIG. 11 and FIG. 12, in some embodiments, the touch layer 5 includes a touch electrode 511 and a dummy electrode 512 independent of each other, and at least part of the touch electrode 511 and the dummy electrode 512 are reused as the third light shielding sub-layer 203.

Exemplarily, both the touch electrode and the dummy electrode are made of conductive materials such as metal materials, but the present disclosure is not limited to this. The touch electrode is used to drive or receive a touch signal to achieve a touch function. The dummy electrode 512 includes a floating electrode and does not receive electrical signals. It should be noted that the dummy electrode may be provided or not according to actual needs.

The touch electrode 511 and the dummy electrode 512 may be located in a separate conductive layer. Alternatively, the touch electrode 511 and the dummy electrode 512 may be located in two stacked conductive layers.

By providing the touch electrode 511 and the dummy electrode 512 independent of each other in the touch layer, a touch signal strength may be better optimized and a touch performance may be improved. As shown in FIG. 11, in some embodiments, the touch electrode 511 includes an active electrode portion 5110. The third light shielding sub-layer 203 included in the touch electrode 511 is coupled to the active electrode portion 5110.

The active electrode portion 5110 is mainly used to implement the touch function. The third light shielding sub-layer 203 included in the touch electrode is coupled to the active electrode portion 5110, so that the third light shielding sub-layer 203 included in the touch electrode 511 is equivalent to increasing an area of the active electrode portion while achieving the light shielding function, thereby increasing an amount of touch signals, better optimizing the touch signal strength and further improving the touch performance.

In some embodiments, an orthographic projection of the third light shielding sub-layer 203 included in the touch electrode on the base substrate is surrounded at least partially by an orthographic projection of the active electrode portion 5110 on the base substrate.

The above-mentioned arrangement not only ensures a light shielding effect of the third light shielding sub-layer 203, but also ensures a sufficient layout space for the active electrode portion 5110, thereby ensuring a touch effect of the touch display panel.

In some embodiments, referring to FIG. 12, the dummy electrode 512 includes a dummy electrode portion 5120. The dummy electrode portion 5120 may be a floating electrode and does not receive signals. The third light shielding sub-layer 203 included in the dummy electrode 512 is coupled to at least part of the dummy electrode portion 5120. Alternatively, the third light shielding sub-layer 203 included in the dummy electrode 512 is independent of the dummy electrode portion 5120.

The above-mentioned different layouts may be selected according to actual needs. Whether the third light shielding sub-layer 203 included in the dummy electrode 512 is coupled to the dummy electrode portion 5120 or not, it is possible to produce a technical effect of optimizing the touch signal strength and improving the touch performance.

Exemplarily, in some embodiments of the present disclosure, referring to FIG. 9, the pixel definition layer PDL may be made of a black material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 8 microns to 20 microns, but the present disclosure is not limited to this. The touch layer 5 may consist of one or more layers of metal mesh. The touch layer 5 includes a plurality of metal wires. For example, the touch layer 5 includes a plurality of touch sub-lines 51 between the plurality of peeping prevention sub-pixels. An orthographic projection of at least part of the touch sub-lines 51 on the base substrate has a third width d3 in the first direction, and the third width d3 ranges from 2 microns to 4 microns. Lower surfaces of at least part of the plurality of metal wires close to the base substrate are blackened, so that stray light may be reduced.

A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure 7 ranges from 8 microns to 40 microns, but the present disclosure is not limited to this. The lens structure is made of a high refractive index material. For example, the material in the lens structure 7 may have a refractive index from 1.5 to 1.8, but the present disclosure is not limited to this. A material around the lens structure 7 is a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 9, the display panel further includes a second light shielding sub-layer 202 between the touch layer 5 and the encapsulation layer 3. The second light shielding sub-layer 202 includes a plurality of second light shielding sub-portions 2021. An orthographic projection of at least one second light shielding sub-portion 2021 on the base substrate has a sixth width d6 in the first direction. The sixth width d6 ranges from 4 microns to 20 microns, but the present disclosure is not limited to this.

Exemplarily, the display panel may further include a second covering layer 13 between the second light shielding sub-layer 202 and the second protective layer 4. The second covering layer 13 may be a transparent insulation layer.

Exemplarily, the second light shielding sub-layer 202 defines a plurality of second openings 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate. For example, a distance between the orthographic projection of the boundary of the peeping prevention pixel opening 32 on the base substrate and the orthographic projection of the boundary of the corresponding second opening region 212 on the base substrate ranges from −3 microns to 10 microns, or from −1 micron to 10 microns, such as 0 to 6 microns.

It should be noted that, when the above-mentioned distance is a positive value, it means that the orthographic projection of the boundary of the peeping prevention pixel opening 32 on the base substrate does not overlap with the orthographic projection of the second light shielding sub-layer 202 on the base substrate; and when the above-mentioned distance is a negative value, it means that the orthographic projection of the boundary of the peeping prevention pixel opening 32 on the base substrate overlaps with the orthographic projection of the second light shielding sub-layer 202 on the base substrate.

Exemplarily, in some embodiments of the present disclosure, the second light shielding sub-layer 202 has a second thickness h2, and the encapsulation layer 3 has a fourth thickness h4. A ratio of the second thickness h2 to the fourth thickness h4 is greater than or equal to 0.05 and less than or equal to 0.5. For example, the second thickness h2 ranges from 1 micron to 3 microns, and the fourth thickness h4 ranges from 2 microns to 20 microns, such as 8 microns to 20 microns.

Exemplarily, referring to FIG. 10, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 9 provided with the lens structure is greatly improved in the brightness of the peeping prevention pixel region in a front viewing angle range (for example, −20° to 20°, or −30° to 30°), for example, the brightness near the 0° viewing angle is increased by about 300%, which helps further improve the display effect of the display panel in the peeping prevention mode.

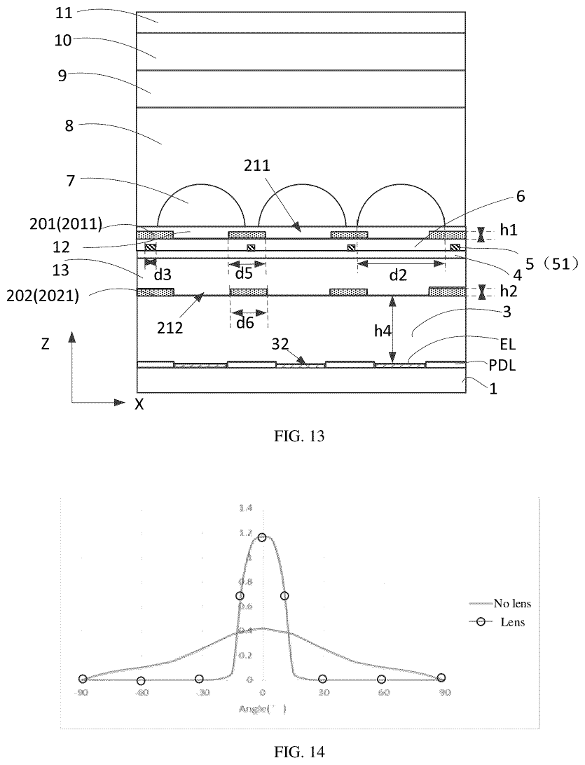

FIG. 13 shows a schematic partial cross-sectional view of a display panel according to other embodiments of the present disclosure, taken along line AA′ in FIG. 2; FIG. 14 shows a comparison diagram of a light output effect of display panels with/without a lens structure in FIG. 13.

Exemplarily, in some embodiments of the present disclosure, referring to FIG. 13, the pixel definition layer PDL may be made of a black material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 8 microns to 20 microns, but the present disclosure is not limited to this. The touch layer 5 may consist of one or more layers of metal mesh. The touch layer 5 includes a plurality of metal wires. For example, the touch layer 5 includes a plurality of touch sub-lines 51 between the plurality of peeping prevention sub-pixels. An orthographic projection of at least part of the touch sub-lines 51 on the base substrate has a third width d3 in the first direction, and the third width d3 ranges from 2 microns to 4 microns. Lower surfaces of at least part of the plurality of metal wires close to the base substrate are blackened, so that stray light may be reduced.

A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure 7 ranges from 8 microns to 40 microns, but the present disclosure is not limited to this. The lens structure is made of a high refractive index material. For example, the material in the lens structure 7 may have a refractive index from 1.5 to 1.8, but the present disclosure is not limited to this. A material around the lens structure 7 is a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 13, the light shielding layer may further include a first light shielding sub-layer 201 between the touch layer 5 and the lens structure 7. A first covering layer 12 may be filled between the lens structure 7 and the first light shielding sub-layer 201. The first covering layer 12 may cover an upper surface of the first light shielding sub-layer 201, so that a surface of the lens structure 7 close to the base substrate is spaced apart from a surface of the first light shielding sub-layer 201 away from the base substrate, which means that the lens structure 7 is not in direct contact with the first light shielding sub-layer 201. The first light shielding sub-layer 201 includes a plurality of first light shielding sub-portions 2011. An orthographic projection of at least one first light shielding sub-portion 2011 on the base substrate has a fifth width d5 in the first direction. The fifth width d5 may range from 4 microns to 20 microns, but the present disclosure is not limited to this.

Exemplarily, the refractive index of the material in the first covering layer 12 is less than that of the material in the lens structure 7, so that the lens structure has a better light concentration.

Exemplarily, the first light shielding sub-layer 201 defines a plurality of first opening regions 211. An orthographic projection of a boundary of the peeping prevention pixel opening 32 on the base substrate is surrounded by an orthographic projection of a boundary of a corresponding first opening region 211 on the base substrate. Alternatively, an orthographic projection of the peeping prevention pixel opening 32 on the base substrate at least partially overlaps with an orthographic projection of the first light shielding sub-layer 201 on the substrate.

Continuing to refer to FIG. 13, the light shielding layer may further include a second light shielding sub-layer 202 between the touch layer 5 and the encapsulation layer 3. The second light shielding sub-layer 202 includes a plurality of second light shielding sub-portions 2021. An orthographic projection of at least one second light shielding sub-portion 2021 on the base substrate has a sixth width d6 in the first direction. The sixth width d6 ranges from 4 microns to 20 microns, but the present disclosure is not limited to this.

Exemplarily, the display panel may further include a second covering layer 13 between the second light shielding sub-layer 202 and the second protective layer 4. Both the second protective layer 4 and the second covering layer 13 may be transparent insulation layers.

Exemplarily, the second light shielding sub-layer 202 defines a plurality of second opening regions 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate.

Exemplarily, an orthographic projection of a first light shielding sub-layer 201 corresponding to a peeping prevention pixel opening on the base substrate may overlap completely with an orthographic projection of a second light shielding sub-layer 202 corresponding to the same peeping prevention pixel opening on the base substrate. Alternatively, an orthographic projection of a first light shielding sub-layer 201 corresponding to a peeping prevention pixel opening on the base substrate may overlap at least partially with an orthographic projection of a second light shielding sub-layer 202 corresponding to the same peeping prevention pixel opening on the base substrate.

Exemplarily, in some embodiments of the present disclosure, the first light shielding sub-layer 201 has a first thickness h1, and the encapsulation layer 3 has a fourth thickness h4. A ratio of the first thickness h1 to the fourth thickness h4 is greater than or equal to 0.05 and less than or equal to 0.5. For example, the first thickness h1 ranges from 1 micron to 3 microns, and the fourth thickness h4 ranges from 2 microns to 20 microns, such as 8 microns to 20 microns.

Exemplarily, in some embodiments of the present disclosure, the second light shielding sub-layer 202 has a second thickness h2, and the encapsulation layer 3 has a fourth thickness h4. A ratio of the second thickness h2 to the fourth thickness h4 is greater than or equal to 0.05 and less than or equal to 0.5. For example, the second thickness h2 ranges from 1 micron to 3 microns, and the fourth thickness h4 ranges from 2 microns to 20 microns, such as 8 microns to 20 microns.

Through a combined design of the first light shielding sub-layer 201 and the second light shielding sub-layer 202, the light emitted by the peeping prevention sub-pixel is emitted sequentially from the second opening region 212 and the first opening region 211 to the light output side of the display panel, so that the display panel may achieve the peeping prevention mode through the peeping prevention sub-pixels.

Exemplarily, referring to FIG. 14, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 13 provided with the lens structure is greatly improved in the brightness of the peeping prevention pixel region in a front viewing angle range (for example, −10° to 10°, or −20° to 20°), for example, the brightness near the 0° viewing angle is increased by about 300%.

Compared with a display panel provided with a single light shielding layer, a display panel provided with double light shielding layers has a more concentrated light output angle in the peeping prevention pixel region, so that the viewing angle is further reduced, and the light output intensity is close to 0 in a larger viewing angle range (such as −90° to −30° and 30° to 90°). The design of double light shielding layers may further optimize the light output effect of the peeping prevention pixel region, better reduce the viewing angle and increase the front light intensity, thereby achieving a better peeping prevention display effect.

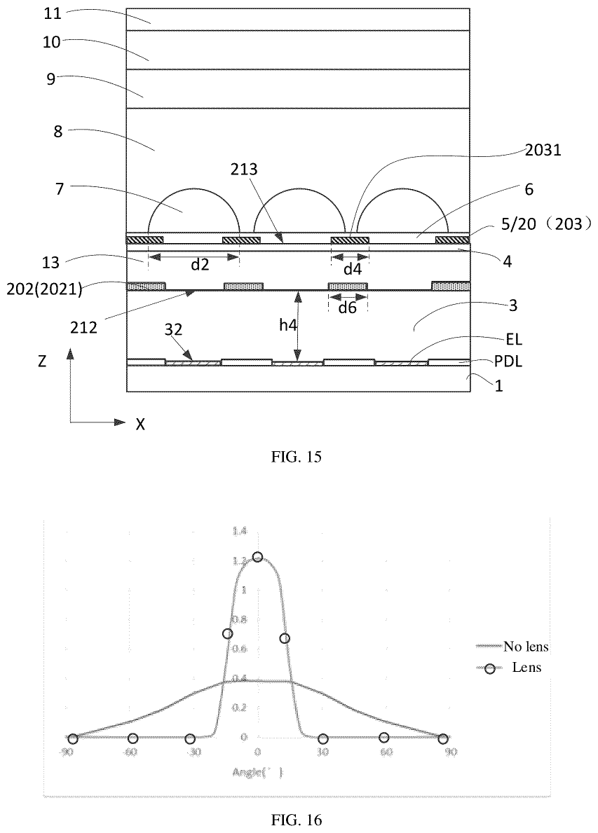

FIG. 15 shows a schematic partial cross-sectional view of a display panel according to other embodiments of the present disclosure, taken along line AA′ in FIG. 2; FIG. 16 shows a comparison diagram of a light output effect of display panels with/without a lens structure in FIG. 15.

Exemplarily, in some embodiments of the present disclosure, referring to FIG. 15, the pixel definition layer PDL may be made of a black material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 8 microns to 20 microns, but the present disclosure is not limited to this. The touch layer 5 may consist of one or more layers of metal mesh. The touch layer 5 includes a plurality of metal wires. Lower surfaces of at least part of the plurality of metal wires close to the base substrate are blackened, so that stray light may be reduced. At least part of the plurality of metal wires are reused as the third light shielding sub-layer 203. The third light shielding sub-layer 203 defines a plurality of third opening regions 213, and an orthographic projection of the third opening region 213 on the base substrate at least partially overlaps with the orthographic projection of the corresponding lens structure 7 on the base substrate.

Exemplarily, continuing to refer to FIG. 15, the third light shielding sub-layer 203 may include a plurality of third light shielding sub-portions 2031. An orthographic projection of the third light shielding sub-portion 2031 on the base substrate defines the corresponding third opening region 213. An orthographic projection of the third light shielding sub-portion 2031 on the base substrate at least partially overlaps with the orthographic projection of the lens structure 7 on the base substrate.

Exemplarily, an orthographic projection of a boundary of the peeping prevention pixel opening 32 on the base substrate is surrounded by an orthographic projection of a boundary of a corresponding third opening region 213 on the base substrate. Alternatively, an orthographic projection of the peeping prevention pixel opening 32 on the base substrate at least partially overlaps with an orthographic projection of the third light shielding sub-layer 203 on the base substrate. For example, a distance between the orthographic projection of the boundary of the peeping prevention pixel opening 32 on the base substrate and the orthographic projection of the boundary of the corresponding third opening region 213 on the base substrate ranges from −3 microns to 10 microns, or from −1 micron to 10 microns, such as 0 to 6 microns.

A first protective layer 6 may be provided on the touch layer 5, and a thickness of the first protective layer 6 ranges from 2 microns to 5 microns, but the present disclosure is not limited to this. The lens structure 7 may be a hemispherical or spherical crown structure. The second width d2 of the lens structure ranges from 8 microns to 40 microns, but the present disclosure is not limited to this. The lens structure 7 is made of a high refractive index material. For example, the material in the lens structure 7 may have a refractive index from 1.5 to 1.8, but the present disclosure is not limited to this. A material around the lens structure 7 is a low refractive index material, which will not be described in detail here.

Continuing to refer to FIG. 15, the orthographic projection of at least part of the third light shielding sub-portions 2031 on the base substrate has a fourth width d4 in the first direction X. A ratio of the fourth width d4 to the second width d2 ranges from 0.2 to 0.8, such as about 0.5. For example, the fourth width d4 ranges from 4 microns to 20 microns, but the present disclosure is not limited to this.

Continuing to refer to FIG. 15, the light shielding layer may further include a second light shielding sub-layer 202 between the touch layer 5 and the encapsulation layer 3. The second light shielding sub-layer 202 includes a plurality of second light shielding sub-portions 2021. An orthographic projection of at least one second light shielding sub-portion 2021 on the base substrate has a sixth width d6 in the first direction. The sixth width d6 ranges from 4 microns to 20 microns, but the present disclosure is not limited to this.

Exemplarily, the display panel may further include a second covering layer 13 between the second light shielding sub-layer 202 and the second protective layer 4. The second covering layer 13 may be a transparent insulation layer.

Exemplarily, the second light shielding sub-layer 202 defines a plurality of second opening regions 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate.

Exemplarily, an orthographic projection of a third light shielding sub-layer 203 corresponding to a peeping prevention pixel opening on the base substrate may overlap completely with an orthographic projection of a second light shielding sub-layer 202 corresponding to the same peeping prevention pixel opening on the base substrate.

Exemplarily, an orthographic projection of a third light shielding sub-layer 203 corresponding to a peeping prevention pixel opening on the base substrate may overlap at least partially with an orthographic projection of a second light shielding sub-layer 202 corresponding to the same peeping prevention pixel opening on the base substrate.

Through a combined design of the second light shielding sub-layer 202 and the third light shielding sub-layer 203, the light emitted by the peeping prevention sub-pixel is emitted sequentially from the second opening region 212 and the third opening region 213 to the light output side of the display panel, so that the display panel may achieve the peeping prevention mode through the peeping prevention sub-pixels. Furthermore, by reusing at least part of the touch layer as the third light shielding sub-layer 203, it is avoided to form a third light shielding sub-layer 203 specially used for shielding light in the touch display panel, so that the number of film layers in the touch display panel is reduced, an internal structure of the touch display panel is optimized, and problems of complex structure, large product-thickness and high production cost of a display product having a function of switching between the peeping prevention mode and the screen information share mode may be solved.

Exemplarily, referring to FIG. 16, the horizontal axis represents different viewing angle ranges of the peeping prevention pixel region, and the vertical axis represents relative light output intensities of two display panels with and without lens structure (other structures are the same) in different viewing angle ranges. Through comparison, it is found that the display panel of the embodiments shown in FIG. 15 provided with the lens structure is greatly improved in the brightness of the peeping prevention pixel region in a front viewing angle range (for example, −10° to 10°, or −20° to 20°), for example, the brightness near the 0° viewing angle is increased by about 300%.

Compared with a display panel provided with a single light shielding layer, a display panel provided with double light shielding layers has a more concentrated light output angle in the peeping prevention pixel region, so that the viewing angle is further reduced, and the light output intensity is close to 0 in a larger viewing angle range (such as −90° to −30° and 30° to 90°). The design of double light shielding layers may further optimize the light output effect of the peeping prevention pixel region, better reduce the viewing angle and increase the front light intensity, thereby achieving a better peeping prevention display effect.

FIG. 17 shows a schematic partial cross-sectional view of a display panel according to other embodiments of the present disclosure, taken along line AA′ in FIG. 2.

Exemplarily, in some embodiments of the present disclosure, referring to FIG. 17, the pixel definition layer PDL may be made of a black material or a transparent material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 6 microns to 20 microns, but the present disclosure is not limited to this. The touch layer 5 may consist of one or more layers of metal mesh. The touch layer 5 includes a plurality of metal wires. For example, the touch layer 5 includes a plurality of touch sub-lines 51 between the plurality of peeping prevention sub-pixels. An orthographic projection of at least part of the touch sub-lines 51 on the base substrate has a third width d3 in the first direction, and the third width d3 ranges from 2 microns to 4 microns.

Exemplarily, lower surfaces of at least part of the plurality of metal wires close to the base substrate are blackened, so that stray light may be reduced.

Exemplarily, lower surfaces of the plurality of metal wires close to the base substrate may not be blackened.

A first protective layer 6 may be provided on the touch layer 5, and the first protective layer 6 may include a single organic layer or a stack structure formed by inorganic layer/organic layer/inorganic layer. Exemplarily, the first protective layer 6 may further include a single inorganic layer, such as SiNx; or the first protective layer 6 may further include a stack structure formed by a plurality of inorganic layers, such as a SiNx/SiOx stack layer. Exemplarily, a thickness of the first protective layer 6 ranges from 0.1 microns to 5 microns, but the present disclosure is not limited to this.

The lens structure 7 may be a hemispherical or spherical crown structure. The second width d2 of the lens structure ranges from 6 microns to 40 microns, but the present disclosure is not limited to this. The lens structure is made of a high refractive index material. For example, the material in the lens structure 7 may have a refractive index from 1.5 to 1.8, but the present disclosure is not limited to this. A material around the lens structure 7 is a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 17, the light shielding layer may further include a first light shielding sub-layer 201 between the touch layer 5 and the lens structure 7.

Exemplarily, at least part of the first light shielding sub-layer 201 may be in direct contact with the lens structure 7.

Exemplarily, referring to FIG. 13, a first covering layer 12 may be filled between the first light shielding sub-layer 201 and the lens structure 7. The first covering layer 12 may cover an upper surface of the first light shielding sub-layer 201, so that a surface of the lens structure 7 close to the base substrate is spaced apart from a surface of the first light shielding sub-layer 201 away from the base substrate, which means that the lens structure 7 is not in direct contact with the first light shielding sub-layer 201.

An orthographic projection of the first light shielding sub-portion 2011 on the base substrate has a fifth width d5 in the first direction. The fifth width d5 ranges from 4 microns to 20 microns, but the present disclosure is not limited to this.

Exemplarily, the first light shielding sub-layer 201 defines a plurality of first opening regions 211. An orthographic projection of a boundary of the peeping prevention pixel opening 32 on the base substrate is surrounded by an orthographic projection of a boundary of a corresponding first opening region 211 on the base substrate. Alternatively, an orthographic projection of the peeping prevention pixel opening 32 on the base substrate at least partially overlaps with an orthographic projection of the first light shielding sub-layer 201 on the base substrate. For example, a distance between the orthographic projection of the boundary of the peeping prevention pixel opening 32 on the base substrate and the orthographic projection of the boundary of the corresponding first opening region 211 on the base substrate ranges from −1 micron to 10 microns, such as 0 to 8 microns.

Exemplarily, the first light shielding sub-layer 201 includes a third surface 2010 close to the base substrate, and the first surface EL1 is spaced apart from the third surface 2010 by a third spacing distance H3. The third spacing distance H3 is less than or equal to the first spacing distance H1.

Exemplarily, the third spacing distance H3 ranges from 10 microns to 30microns, such as 12 microns to 20 microns.

Exemplarily, the first light shielding sub-layer 201 has a first thickness h1, and the encapsulation layer 3 has a fourth thickness h4. A ratio of the first thickness h1 to the fourth thickness h4 is greater than or equal to 0.05 and less than or equal to 0.5. For example, the first thickness h1 ranges from 1 micron to 3 microns, and the fourth thickness h4 ranges from 2 microns to 20 microns, such as 8 microns to 20 microns.

Continuing to refer to FIG. 17, the light shielding layer may further include a second light shielding sub-layer 202 between the touch layer 5 and the encapsulation layer 3. The second light shielding sub-layer 202 includes a plurality of second light shielding sub-portions 2021. An orthographic projection of at least one second light shielding sub-portion 2021 on the base substrate has a sixth width d6 in the first direction. The sixth width d6 ranges from 4 microns to 20 microns, but the present disclosure is not limited to this.

Exemplarily, the display panel may further include a second covering layer 13 between the second light shielding sub-layer 202 and the second protective layer 4. The second covering layer 13 may be a transparent insulation layer.

Exemplarily, the second light shielding sub-layer 202 defines a plurality of second opening regions 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate. For example, a distance between the orthographic projection of the boundary of the peeping prevention pixel opening 32 on the base substrate and the orthographic projection of the boundary of the corresponding second opening region 212 on the base substrate ranges from −3 microns to 10 microns, such as 0 to 6 microns.

Exemplarily, the second light shielding sub-layer 202 includes a fourth surface 2020 close to the base substrate, and the first surface EL1 is spaced apart from the fourth surface 2020 by a fourth spacing distance H4. A ratio of the fourth spacing distance H4 to the first width d1 is greater than or equal to 1 and less than or equal to 2.

Exemplarily, the fourth spacing distance H4 ranges from 6 microns to 12 microns, such as 8 microns to 10 microns, and the first width is less than or equal to 6 microns.

Exemplarily, a ratio of the fourth spacing distance H4 to the third spacing distance H3 is greater than or equal to 0.2 and less than or equal to 0.85.

By reducing the distance between the first light shielding sub-layer and the light emitting layer and the distance between the second light shielding sub-layer and the light emitting layer, a distance between the light emitting layer and the lens above the light shielding layer may be reduced accordingly, which is conducive to the convergence of light, so as to achieve a better peeping prevention display effect.

Exemplarily, an orthographic projection of a first light shielding sub-layer 201 corresponding to a peeping prevention pixel opening on the base substrate falls within an orthographic projection of a second light shielding sub-layer 202 corresponding to the same peeping prevention pixel opening on the base substrate. That is, the first opening region 211 has a larger opening range than the second opening region 212. By optimizing sizes of the first opening region and the second opening region, it is possible to better control light to emit to the region where the lens structure is located, thereby improving the display brightness in the peeping prevention state.

Exemplarily, in some embodiments of the present disclosure, the first light shielding sub-layer 201 has a first thickness h1, and the encapsulation layer 3 has a fourth thickness h4. A ratio of the first thickness h1 to the fourth thickness h4 is greater than or equal to 0.05 and less than or equal to 0.5. For example, the first thickness h1 ranges from 1 micron to 3 microns, and the fourth thickness h4 ranges from 2 microns to 20 microns, such as 8 microns to 20 microns.

Exemplarily, in some embodiments of the present disclosure, the second light shielding sub-layer 202 has a second thickness h2, and the encapsulation layer 3 has a fourth thickness h4. A ratio of the second thickness h2 to the fourth thickness h4 is greater than or equal to 0.05 and less than or equal to 0.5. For example, the second thickness h2 ranges from 1 micron to 3 microns, and the fourth thickness h4 ranges from 2 microns to 20 microns, such as 8 microns to 20 microns.

Through a combined design of the first light shielding sub-layer 201 and the second light shielding sub-layer 202, the light emitted by the peeping prevention sub-pixel is emitted sequentially from the second opening region 212 and the first opening region 211 to the light output side of the display panel, so that the display panel may achieve the peeping prevention mode through the peeping prevention sub-pixels.

Compared with a display panel provided with a single light shielding layer, a display panel provided with double light shielding layers has a more concentrated light output angle in the peeping prevention pixel region, so that the viewing angle is further reduced, and the light output intensity is close to 0 in a larger viewing angle range (such as −90° to −30° and 30° to 90°). The double light shielding layers may include different opening regions. By optimizing the sizes of the opening regions corresponding to the upper and lower light shielding layers, it is possible to further optimize the light output effect of the peeping prevention pixel region, better reduce the viewing angle and increase the front light intensity, thereby achieving a better peeping prevention display effect.

FIG. 18 shows a schematic partial cross-sectional view of a display panel according to other embodiments of the present disclosure, taken along line AA′ in FIG. 2.

Exemplarily, in some embodiments of the present disclosure, referring to FIG. 18, the pixel definition layer PDL may be made of a black material or a transparent material. The encapsulation layer 3 may adopt thin film encapsulation, such as inorganic/organic/inorganic three-layer or multi-layer structure. Exemplarily, the encapsulation layer 3 has a fourth thickness h4, which ranges from 2 microns to 20 microns, such as 6 microns to 20 microns, but the present disclosure is not limited to this. The touch layer 5 may consist of one or more layers of metal mesh. The touch layer 5 includes a plurality of metal wires. At least part of the plurality of metal wires are reused as the third light shielding sub-layer 203. The third light shielding sub-layer 203 defines a plurality of third opening regions 213, and an orthographic projection of the third opening region 213 on the base substrate at least partially overlaps with an orthographic projection of the corresponding lens structure 7 on the base substrate.

Exemplarily, the light emitting layer of the peeping prevention sub-pixel includes a first surface EL1 away from the base substrate, and the lens structure 7 includes a second surface 71 close to the base substrate. The first surface EL1 is spaced apart from the second surface 71 by a first spacing distance H1. The first spacing distance H1 is less than twice the fourth thickness h4. For example, the first spacing distance may be 14 microns, and the fourth thickness may be 8 microns.

Exemplarily, the first spacing distance H1 is less than twice the fourth thickness h4. For example, the first spacing distance H1 may be 14 microns, and the fourth thickness h4 may be 8 microns.

Exemplarily, continuing to refer to FIG. 18, the third light shielding sub-layer 203 may include a plurality of third light shielding sub-portions 2031. The plurality of third light shielding sub-portions 2031 define corresponding third opening regions 213. An orthographic projection of the third light shielding sub-portion 2031 on the base substrate at least partially overlaps with the orthographic projection of the lens structure 7 on the base substrate.

Exemplarily, an orthographic projection of a boundary of the peeping prevention pixel opening 32 on the base substrate is surrounded by an orthographic projection of a boundary of a corresponding third opening region 213 on the base substrate. Alternatively, an orthographic projection of the peeping prevention pixel opening 32 on the base substrate at least partially overlaps with an orthographic projection of the third light shielding sub-layer 203 on the base substrate. For example, a distance between the orthographic projection of the boundary of the peeping prevention pixel opening 32 on the base substrate and the orthographic projection of the boundary of the corresponding third opening region 213 on the base substrate ranges from −1 micron to 10 microns, such as 0 to 8 microns.

Continuing to refer to FIG. 18, an orthographic projection of at least part of the third light shielding sub-portions 2031 on the base substrate has a fourth width d4 in the first direction. A ratio of the fourth width d4 to the second width d2 ranges from 0.2 to 0.8, such as about 0.5. For example, the fourth width d4 ranges from 3 microns to 20 microns, but the present disclosure is not limited to this.

Exemplarily, the third light shielding sub-layer 203 has a third thickness h3. A ratio of the third thickness h3 to the fourth thickness h4 is greater than or equal to 0.005 and less than or equal to 0.5. For example, the third thickness h3 ranges from 0.1 microns to 3 microns, and the fourth thickness h4 ranges from 2 microns to 20 microns, such as 8 microns to 20 microns. By providing a thin third light shielding sub-layer 203, it is possible to increase a flatness of the film layer, which helps the formation of the lens structure above the light shielding layer.

Exemplarily, the third light shielding sub-layer 203 includes a fifth surface 2030 close to the base substrate, and the first surface EL1 is spaced from the fifth surface 2030 by a fifth spacing distance H5. The fifth spacing distance H5 ranges from 10 microns to 30 microns, such as 12 microns to 20 microns.

A first protective layer 6 may be provided on the touch layer 5, and the first protective layer 6 may include a single organic layer or a stack structure formed by inorganic layer/organic layer/inorganic layer. Exemplarily, the first protective layer 6 may further include a single inorganic layer, such as SiNx; or the first protective layer 6 may further include a stack structure formed by a plurality of inorganic layers, such as a SiNx/SiOx stack layer. Exemplarily, a thickness of the first protective layer 6 ranges from 0.1 microns to 5 microns, but the present disclosure is not limited to this.

The lens structure 7 may be a hemispherical or spherical crown structure. The second width d2 of the lens structure 7 ranges from 6 microns to 40 microns, but the present disclosure is not limited to this. The lens structure 7 is made of a high refractive index material. For example, the material in the lens structure 7 may have a refractive index from 1.5 to 1.8, but the present disclosure is not limited to this. A material around the lens structure 7 is a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 18, the light shielding layer may further include a second light shielding sub-layer 202 between the touch layer 5 and the encapsulation layer 3. The second light shielding sub-layer 202 includes a plurality of second light shielding sub-portions 2021. An orthographic projection of the second light shielding sub-portion 2021 on the base substrate has a sixth width d6 in the first direction. The sixth width d6 ranges from 4 microns to 20 microns, but the present disclosure is not limited to this.

Exemplarily, the display panel may further include a second covering layer 13 between the second light shielding sub-layer 202 and the second protective layer 4. The second covering layer 13 may be a transparent insulation layer.

Exemplarily, the second light shielding sub-layer 202 defines a plurality of second opening regions 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate. For example, a distance between the orthographic projection of the boundary of the peeping prevention pixel opening 32 on the base substrate and the orthographic projection of the boundary of the corresponding second opening region 212 on the base substrate ranges from −3 microns to 10 microns, such as 0 to 6 microns.

Exemplarily, the second light shielding sub-layer 202 includes a fourth surface 2020 close to the base substrate, and the first surface EL1 is spaced apart from the fourth surface 2020 by a fourth spacing distance H4. A ratio of the fourth spacing distance H4 to the first width d1 is greater than or equal to 1 and less than or equal to 2.

Exemplarily, the fourth spacing distance H4 ranges from 6 microns to 12 microns, such as 8 microns to 10 microns, and the first width d1 is less than or equal to 6 microns.

Exemplarily, a ratio of the fourth spacing distance H4 to the fifth spacing distance H5 is greater than or equal to 0.2 and less than or equal to 0.85.

By reducing the distance between the third light shielding sub-layer 203 and the light emitting layer EL and the distance between the second light shielding sub-layer 202 and the light emitting layer EL, a distance between the light emitting layer and the lens above the light shielding layer may be reduced accordingly, which is conducive to the convergence of light, so as to achieve a better peeping prevention display effect.

Exemplarily, an orthographic projection of a third light shielding sub-layer 203 corresponding to a peeping prevention pixel opening on the base substrate falls within an orthographic projection of a second light shielding sub-layer 202 corresponding to the same peeping prevention pixel opening on the base substrate. That is, the third opening region 213 has a larger opening range than the second opening region 212. By optimizing sizes of the third opening region and the second opening region, it is possible to better control the light to emit to the region where the lens structure is located, thereby improving the display brightness in the peeping prevention state.

Exemplarily, in some embodiments of the present disclosure, the second light shielding sub-layer 202 has a second thickness h2, and the encapsulation layer 3 has a fourth thickness h4. A ratio of the second thickness h2 to the fourth thickness h4 is greater than or equal to 0.05 and less than or equal to 0.5. For example, the second thickness h2 ranges from 1 micron to 3 microns, and the fourth thickness h4 ranges from 2 microns to 20 microns, such as 8 microns to 20 microns.

Through a combined design of the third light shielding sub-layer 203 and the second light shielding sub-layer 202, the light emitted by the peeping prevention sub-pixel is emitted sequentially from the second opening region 212 and the third opening region 213 to the light output side of the display panel, so that the display panel may achieve the peeping prevention mode through the peeping prevention sub-pixels.

Compared with a display panel provided with a single light shielding layer, a display panel provided with double light shielding layers has a more concentrated light output angle in the peeping prevention pixel region, so that the viewing angle is further reduced, and the light output intensity is close to 0 in a larger viewing angle range (such as −90° to −30° and 30° to 90°). The double light shielding layers may include different opening regions. By optimizing the sizes of the opening regions corresponding to the upper and lower light shielding layers, it is possible to further optimize the light output effect of the peeping prevention pixel region, better reduce the viewing angle and increase the front light intensity, thereby achieving a better peeping prevention display effect.

By reusing at least part of the touch layer as the third light shielding sub-layer 203, it is avoided to form a third light shielding sub-layer 203 specially used for shielding light in the touch display panel, so that the number of film layers in the touch display panel is reduced, an internal structure of the touch display panel is optimized, and problems of complex structure, large product-thickness and high production cost of a display product having a function of switching between the peeping prevention mode and the screen information share mode may be solved. By reusing at least part of the touch layer as the third light shielding sub-layer 203, it is also possible to reduce the thickness of the third light shielding sub-layer, which helps increase the flatness of the third light shielding sub-layer and helps the formation of the lens structure above the third light shielding sub-layer.

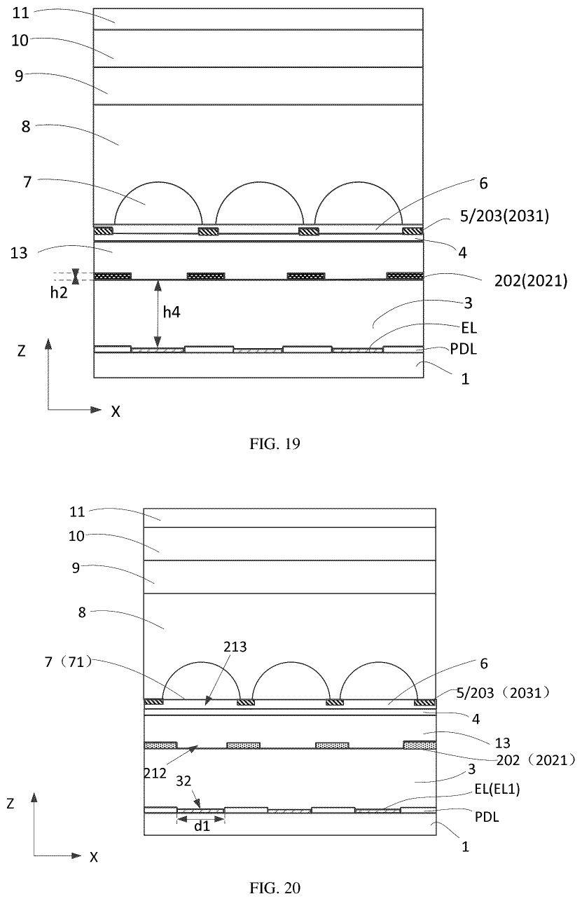

FIG. 19 shows a schematic partial cross-sectional view of a display panel according to other embodiments of the present disclosure, taken along line AA′ in FIG. 2.

Exemplarily, similar to the display panel in the embodiments of FIG. 18, the display panel in FIG. 19 may likewise include a third light shielding sub-layer 203, a second light shielding sub-layer 202, a pixel definition layer PDL, an encapsulation layer 3, a touch layer 5 and a lens structure 7, where at least part of the touch layer is reused as the third light shielding sub-layer 203, the openings of the third light shielding sub-layer 203 and the second light shielding sub-layer 202 are set in the same way, and the distance between the third light shielding sub-layer 203 and the light emitting layer and the distance between the second light shielding sub-layer 202 and the light emitting layer are set in the same way, which will not be repeated here.

Different from the display panel in FIG. 18, the second light shielding sub-layer 202 contains a metal material, and the reflectivity of the metal material of the second light shielding sub-layer is greater than or equal to 20%.

The second light shielding sub-layer 202 has a second thickness h2, and the encapsulation layer 3 has a fourth thickness h4. A ratio of the second thickness h2 to the fourth thickness h4 is greater than or equal to 0.005 and less than or equal to 0.5. For example, the second thickness h2 ranges from 0.1 microns to 3 microns, and the fourth thickness h4 ranges from 2 microns to 20 microns, such as 8 microns to 20 microns.

By designing the second light shielding sub-layer as a thin metal layer and reducing the thickness of the third light shielding sub-layer, it is possible to further increase the flatness of the film layer, which helps the formation of the upper lens structure.

FIG. 20 shows a schematic partial cross-sectional view of a display panel according to other embodiments of the present disclosure, taken along line AA′ in FIG. 2.

Exemplarily, similar to the display panel in the embodiments of FIG. 18, the display panel in FIG. 20 may likewise include a third light shielding sub-layer 203, a second light shielding sub-layer 202, a pixel definition layer PDL, an encapsulation layer 3, a touch layer 5 and a lens structure 7, where at least part of the touch layer is reused as the third light shielding sub-layer 203, which will not be repeated here.

Different from the display panel in FIG. 18, at least part of the third light shielding sub-layer 203 may be in direct contact with the lens structure 7.

Through the design of direct contact between the third light shielding sub-layer 203 and the lens structure 7, an intermediate covering layer may be omitted, which helps reduce the distance between the lens structure and the light emitting layer and improve the light concentration effect of the lens structure, thereby achieving a better display.

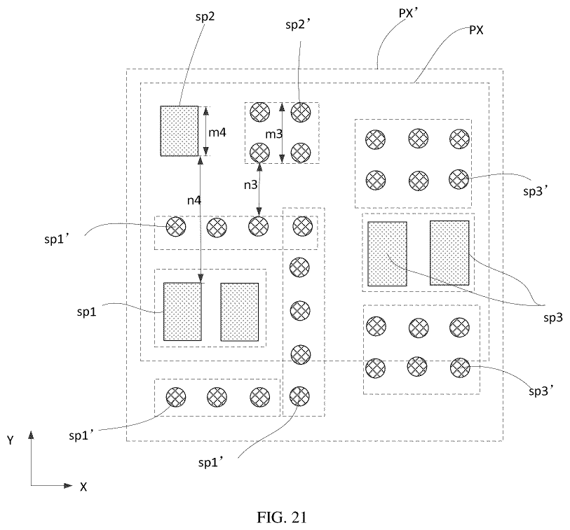

FIG. 21 shows a structure of a portion of the display panel according to some embodiments of the present disclosure.

Exemplarily, in some embodiments of the present disclosure, the display panel may include a plurality of sharing pixel units and a plurality of peeping prevention pixel units, where the sharing pixel units and the peeping prevention pixel units are arranged correspondingly.

Exemplarily, referring to FIG. 21, a sharing pixel unit PX may include a plurality of first sub-pixels sp1, a single second sub-pixel sp2, and a plurality of third sub-pixels sp3.

In some embodiments, the sharing pixel unit PX may include a single first sub-pixel sp1, a single second sub-pixel sp2 and a plurality of third sub-pixels sp3.

In some embodiments, the sharing pixel unit PX may include a plurality of first sub-pixels sp1, a plurality of second sub-pixels sp2 and a plurality of third sub-pixels sp3.

In some embodiments, the sharing pixel unit PX may include a plurality of first sub-pixels sp1, a plurality of second sub-pixels sp2 and a single third sub-pixel sp3.

The number of the first sub-pixels, the second sub-pixels and the third sub-pixels in the sharing pixel unit may be determined according to actual needs, which is not specifically limited in the embodiments of the present disclosure.

Exemplarily, the peeping prevention pixel unit PX′ may include a plurality of fourth sub-pixels sp1′, a plurality of fifth sub-pixels sp2′, and a plurality of sixth sub-pixels sp3′.

Exemplarily, continuing to refer to FIG. 21, the plurality of first sub-pixels sp1 and the plurality of fourth sub-pixels sp1′ are sub-pixels emitting light of the same color, for example, the plurality of first sub-pixels sp1 and the plurality of fourth sub-pixels sp1′ may emit green light. Exemplarily, the number of the plurality of first sub-pixels sp1 is less than the number of the plurality of fourth sub-pixels sp1′. For example, a single sharing pixel unit may include two first sub-pixels sp1, and a single peeping prevention pixel unit may include eleven fourth sub-pixels sp1′. The plurality of first sub-pixels sp1 may be spaced apart in the first direction X and aligned in the second direction Y. In the corresponding peeping prevention pixel unit, the plurality of fourth sub-pixels sp1′ are located in three side regions adjacent to the plurality of first sub-pixels sp1. For example, the plurality of fourth sub-pixels sp1′ may surround the plurality of first sub-pixels sp1 in a U-shape.

Exemplarily, the second sub-pixel sp2 and the plurality of fifth sub-pixels sp2′ are sub-pixels emitting light of the same color, for example, the second sub-pixel sp2 and the plurality of fifth sub-pixels sp2′ may emit red light. The plurality of fifth sub-pixels sp2′ are located in a side region adjacent to the second sub-pixel sp2. For example, the plurality of fifth sub-pixels sp2′ are located in a side region of the second sub-pixel sp2 close to the third sub-pixel sp3. Exemplarily, the plurality of fifth sub-pixels sp2′ are substantially aligned with the second sub-pixel sp2 in the second direction Y.

Exemplarily, the plurality of third sub-pixels sp3 and the plurality of sixth sub-pixels sp3′ are sub-pixels emitting light of the same color, for example, the plurality of third sub-pixels sp3 and the plurality of sixth sub-pixels sp3′ may emit blue light. Exemplarily, the number of the plurality of third sub-pixels sp3 is less than the number of the plurality of sixth sub-pixels sp3′. For example, a single sharing pixel unit may include two third sub-pixels sp3, and a single peeping prevention pixel unit may include twelve sixth sub-pixels sp3′. The plurality of third sub-pixels sp3 may be spaced apart in the first direction X and aligned in the second direction Y.

The plurality of sixth sub-pixels sp3′ are located in two side regions adjacent to the plurality of third sub-pixels sp3, where the two side regions are located on opposite sides of the third sub-pixels sp3. For example, a part of the plurality of sixth sub-pixels sp3′ may be located in a region above the third sub-pixels sp3, and the other part of the plurality of sixth sub-pixels sp3′ may be located in a region below the third sub-pixels sp3. Exemplarily, the plurality of sixth sub-pixels sp3′ and the plurality of third sub-pixels sp3 are substantially aligned in the first direction X.

Exemplarily, in a peeping prevention pixel unit, the plurality of peeping prevention sub-pixels having different colors may be different in terms of a total area of the pixel openings. For example, a total area of the peeping prevention pixel openings of the plurality of sixth sub-pixels sp3′ is larger than a total area of the peeping prevention pixel openings of the plurality of fourth sub-pixels sp1′, and each of the two is larger than the total area of the peeping prevention pixel openings of the plurality of fifth sub-pixels sp2′. For example, the plurality of sixth sub-pixels sp3′ may emit blue light, the plurality of fourth sub-pixels sp1′ may emit green light, and the plurality of fifth sub-pixels sp2′ may emit red light.

Exemplarily, in a sharing pixel unit, the sharing sub-pixels having different colors may be different in terms of the total area of the pixel openings. For example, the total area of the sharing pixel openings of the third sub-pixels sp3 is larger than the total area of the sharing pixel openings of the first sub-pixels sp1, and each of the two is larger than the total area of the sharing pixel openings of the second sub-pixels sp2. For example, the third sub-pixel sp3 may emit blue light, the first sub-pixel sp1 may emit green light, and the second sub-pixel sp2 may emit red light.

It should be noted that a sharing pixel unit may include one or more sharing sub-pixels having the same color.

In some embodiments, in a peeping prevention pixel unit, a plurality of peeping prevention sub-pixels having the same color may be the same or different in terms of shape and size. For example, the peeping prevention sub-pixels may have the same shape and size.

In some embodiments, in a sharing pixel unit, a plurality of sharing sub-pixels having the same color may be the same or different in terms of shape and size. For example, the sharing sub-pixels may have the same shape and size.

In some embodiments, a total area A1 of the peeping prevention pixel openings of the plurality of peeping prevention sub-pixels having the same color in a peeping prevention pixel unit is less than a total area A2 of the pixel openings of the sharing sub-pixels having the same color in a corresponding sharing pixel unit. Exemplarily, a ratio of A1 to A2 is greater than or equal to 0.5 and less than or equal to 1. For example, the ratio of A1 to A2 may be 4/6, or the ratio of A1 to A2 may be 4/7.

In some embodiments, continuing to refer to FIG. 21, in a combination of a single peeping prevention pixel unit and a single sharing pixel unit, a projection of a plurality of peeping prevention sub-pixels having the same color on the base substrate has a maximum coverage width m3 in the second direction Y, and a projection of the sharing sub-pixel corresponding to the plurality of peeping prevention sub-pixels on the base substrate has a maximum coverage width m4 in the second direction Y, where m4 is less than or equal to m3.

In some embodiments, continuing to refer to FIG. 2, in a combination of a single peeping prevention pixel unit and a single sharing pixel unit, a minimum spacing distance between the first sub-pixel sp1 and the second sub-pixel sp2 in the second direction Y is n4, and a minimum spacing distance between the plurality of fourth sub-pixels sp1′ and the plurality of fifth sub-pixels sp2′ in the second direction Y is n3, where n4 is greater than or equal to n3.

It should be noted that the embodiments in FIG. 2 and FIG. 21 are merely schematic illustrations of possible arrangements of sharing pixel units and peeping prevention pixel units, which do not constitute limitations to the present disclosure.

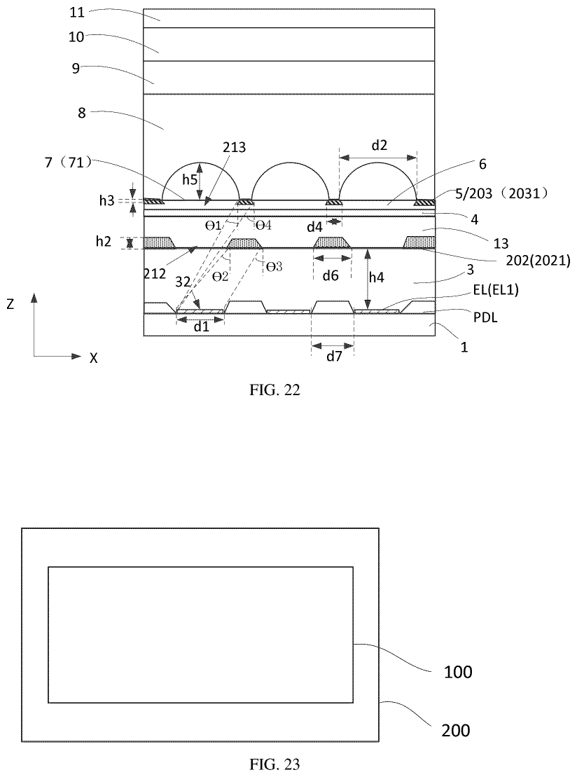

FIG. 22 shows a schematic partial cross-sectional view of a display panel according to other embodiments of the present disclosure, taken along line BB′ in FIG. 21.

Exemplarily, in some embodiments of the present disclosure, referring to FIG. 22, the pixel definition layer PDL may be made of a black material or a transparent material. The encapsulation layer 3 may adopt thin film encapsulation, such as inorganic/organic/inorganic three-layer or multi-layer structure. The touch layer 5 may consist of one or more layers of metal mesh. The touch layer 5 includes a plurality of metal wires. At least part of the plurality of metal wires are reused as the third light shielding sub-layer 203. The third light shielding sub-layer 203 defines a plurality of third opening regions 213, and an orthographic projection of the third opening region 213 on the base substrate at least partially overlaps with an orthographic projection of the corresponding lens structure 7 on the base substrate.

Exemplarily, a projection shape of at least part of the third light shielding sub-layer 203 on a plane where the first direction X and a third direction Z are located may be a rectangle or a trapezoid. The third direction Z may be a direction perpendicular to the base substrate or a light output direction.

Exemplarily, a maximum width of the orthographic projection of the peeping prevention pixel opening 32 on the base substrate in the first direction X is a first width d1, a maximum width of the orthographic projection of the lens structure 7 on the base substrate X in the first direction X is a second width d2, and a ratio of the first width d1 to the second width d2 is less than or equal to 0.6. For example, the first width d1 is less than or equal to 6 microns and the second width d2 ranges from 6 microns to 40 microns, but the present disclosure is not limited to this. For example, the first width d1 may be 6 microns, and the second width d2 may be 11 microns.

By designing a small light emitting area and a relatively large lens structure in the peeping prevention sub-pixel region, it is possible to reduce the viewing angle of the peeping prevention region, which helps improve the peeping prevention effect. Furthermore, it is also possible to improve the display brightness of the peeping prevention region, which helps improve the overall display effect of the display panel.

Continuing to refer to FIG. 22, the orthographic projection of at least part of the third light shielding sub-portion 2031 on the base substrate has a fourth width d4 in the first direction. A ratio of the fourth width d4 to the second width d2 ranges from 0.2 to 0.8, such as about 0.5. The fourth width d4 ranges from 3 microns to 20 microns, but the present disclosure is not limited to this. For example, the fourth width d4 may be 3 microns, and the second width d2 may be 11 microns.

Exemplarily, the third light shielding sub-layer 203 has a third thickness h3. A ratio of the third thickness h3 to the fourth thickness h4 is greater than or equal to 0.005 and less than or equal to 0.5. For example, the third thickness h3 ranges from 0.1 microns to 3 microns, and the fourth thickness h4 ranges from 2 microns to 20 microns, such as 8 microns to 20 microns. For example, the third thickness h3 may be 0.3 microns, and the fourth thickness h4 may be 8 microns. By providing a thin third light shielding sub-layer 203, it is possible to increase a flatness of the film layer, which helps the formation of the lens structure above the light shielding layer.

The lens structure 7 may be a hemispherical or spherical crown structure. For example, the lens structure 7 has a fifth thickness h5 in the third direction Z, where h5 is equal to 5 microns. The lens structure is made of a high refractive index material. For example, the material in the lens structure 7 has a refractive index from 1.5 to 1.8, but the present disclosure is not limited to this. A material around the lens structure 7 is made of a low refractive index material. Exemplarily, the display panel may further include a fourth covering layer 8, an optical adhesive layer 9, a cover plate 10 and a hardened protective layer 11 on the lens structure 7, which will not be described in detail here.

Continuing to refer to FIG. 22, the light shielding layer may further include a second light shielding sub-layer 202 between the touch layer 5 and the encapsulation layer 3. The second light shielding sub-layer 202 includes a plurality of second light shielding sub-portions 2021. An orthographic projection of the second light shielding sub-portion 2021 on the base substrate has a sixth width d6 in the first direction. The sixth width d6 ranges from 4 microns to 20 microns, but the present disclosure is not limited to this. For example, the sixth width d6 is equal to 8 microns.

Exemplarily, a projection shape of at least part of the second light shielding sub-layer 202 on a plane where the first direction X and the third direction Z are located may be a rectangle or a trapezoid.

Exemplarily, the second light shielding sub-layer 202 defines a plurality of second opening regions 212. An orthographic projection of a boundary of the peeping prevention pixel opening 32 on the base substrate is surrounded by an orthographic projection of a boundary of a corresponding second opening region 212 on the base substrate. Alternatively, an orthographic projection of the peeping prevention pixel opening 32 on the base substrate at least partially overlaps with an orthographic projection of the second light shielding sub-layer 202 on the base substrate. For example, a distance between the orthographic projection of the boundary of the peeping prevention pixel opening 32 on the base substrate and the orthographic projection of the boundary of the corresponding second opening region 212 on the base substrate ranges from −3 microns to 10 microns, such as 0 to 6 microns.

Exemplarily, an orthographic projection of a third light shielding sub-layer 203 corresponding to a peeping prevention pixel opening on the base substrate falls within an orthographic projection of a second light shielding sub-layer 202 corresponding to the same peeping prevention pixel opening on the base substrate. That is, the third opening region 213 has a larger opening range than the second opening region 212. By optimizing the sizes of the third opening region and the second opening region, it is possible to better control the light to emit to a region where the lens structure is located, thereby improving the display brightness in the peeping prevention state.

Exemplarily, in some embodiments of the present disclosure, the second light shielding sub-layer 202 has a second thickness h2, and the encapsulation layer 3 has a fourth thickness h4. A ratio of the second thickness h2 to the fourth thickness h4 is greater than or equal to 0.05 and less than or equal to 0.5. For example, the second thickness h2 ranges from 1 micron to 3 microns, and the fourth thickness h4 ranges from 2 microns to 20 microns, such as 8 microns to 20 microns. For example, the second thickness h2 may be equal to 1.5 microns, and the fourth thickness h4 may be equal to 8 microns.

Through a combined design of the third light shielding sub-layer 203 and the second light shielding sub-layer 202, the light emitted by the peeping prevention sub-pixel is emitted sequentially from the second opening region 212 and the third opening region 213 to the light output side of the display panel, so that the display panel may achieve the peeping prevention mode through the peeping prevention sub-pixels.

Exemplarily, continuing to refer to FIG. 22, a line connecting a first side edge of the light emitting layer EL and a side edge of an adjacent third light shielding sub-portion 2031 close to the light emitting layer forms a first light shielding angle θ1 with the third direction Z, a line connecting the first side edge of the light emitting layer EL and a side edge of an adjacent second light shielding sub-portion 2021 close to the light emitting layer forms a second light shielding angle θ2 with the third direction Z, a line connecting a second side edge of the light emitting layer EL and a side edge of the adjacent second light shielding sub-portion 2021 away from the light emitting layer forms a third light shielding angle θ3 with the third direction Z, and a line connecting the first side edge of the light emitting layer EL and a side edge of an adjacent third light shielding sub-portion 2031 away from the light emitting layer forms a fourth light shielding angle θ4 with the third direction Z. The first side edge of the light emitting layer EL refers to a side edge away from the adjacent third light shielding sub-layer 2031, and the second side edge of the light emitting layer EL refers to a side edge close to the adjacent third light shielding sub-layer 2031. Exemplarily, the first light shielding angle θ1 is less than the second light shielding angle θ2, the second light shielding angle θ2 is less than the fourth light shielding angle θ4, and the fourth light shielding angle θ4 is less than the third light shielding angle θ3.

By optimizing the light shielding angles of the plurality of light shielding layers, it is possible to further reduce the viewing angle range of the peeping prevention region, for example, the viewing angle of the peeping prevention region may be reduced to about 25°. It is also possible to increase the brightness at the front viewing angle, for example, the brightness at the front viewing angle may be increased by about 300%, so that the display effect in the peeping prevention mode may be improved.

FIG. 23 shows a schematic structural diagram of a display device provided according to some embodiments of the present disclosure.

Optionally, the embodiments of the present disclosure further provide a touch display device. Referring to FIG. 23, a display device 200 may include but not be limited to e-paper, a mobile phone, a tablet computer, a monitor, a laptop computer, a digital photo frame, a navigator and any other product or component having a display function. It should be understood that the touch display device has the same beneficial effects as the touch display substrate provided in the above-mentioned embodiments.

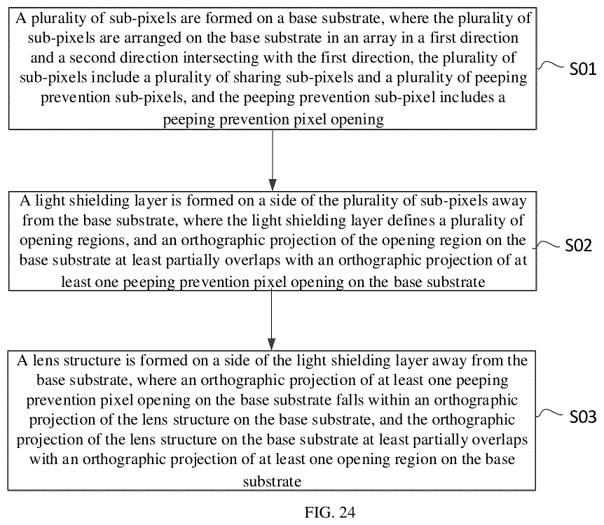

FIG. 24 shows a flowchart of a method of manufacturing a display panel provided according to some embodiments of the present disclosure.

Exemplarily, referring to FIG. 24, the embodiments of the present disclosure further provide a method of manufacturing a display panel. The manufacturing method includes steps S01 to S03.

In step S01, a plurality of sub-pixels are formed on a base substrate, where the plurality of sub-pixels are arranged on the base substrate in an array in a first direction and a second direction intersecting with the first direction. The plurality of sub-pixels include a plurality of sharing sub-pixels and a plurality of peeping prevention sub-pixels, and the peeping prevention sub-pixel includes a peeping prevention pixel opening.

In step S02, a light shielding layer is formed on a side of the plurality of sub-pixels away from the base substrate, where the light shielding layer defines a plurality of opening regions. An orthographic projection of the opening region on the base substrate at least partially overlaps with an orthographic projection of at least one peeping prevention pixel opening on the base substrate.

In step S03, a lens structure is formed on a side of the light shielding layer away from the base substrate. An orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.

Some embodiments of the general concept of the present disclosure have been shown and illustrated. However, it may be understood by those skilled in the art that changes may be made to these embodiments without departing from the principles and spirit of the general concept of the present disclosure, and the scope of the present disclosure is defined by claims and their equivalents.

1. A display panel, comprising:
a base substrate;
a plurality of sub-pixels on the base substrate, wherein the plurality of sub-pixels are arranged in an array in a first direction and a second direction intersecting with the first direction, the plurality of sub-pixels comprise a plurality of sharing sub-pixels and a plurality of peeping prevention sub-pixels, and the peeping prevention sub-pixel comprises a peeping prevention pixel opening;
a light shielding layer on the base substrate, wherein the light shielding layer defines a plurality of opening regions, and an orthographic projection of the opening region on the base substrate at least partially overlaps with an orthographic projection of at least one peeping prevention pixel opening on the base substrate; and
a lens structure on a side of the light shielding layer away from the base substrate,
wherein an orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.

2. The display panel according to claim 1, further comprising:
an encapsulation layer on the base substrate, wherein the encapsulation layer is configured to encapsulate the plurality of sharing sub-pixels and the plurality of peeping prevention sub-pixels; and
a touch layer on a side of the encapsulation layer away from the base substrate, wherein at least one touch electrode is located in the touch layer,
wherein the light shielding layer comprises at least one of a first light shielding sub-layer, a second light shielding sub-layer or a third light shielding sub-layer, the first light shielding sub-layer is located between the touch layer and the lens structure, the second light shielding sub-layer is located between the touch layer and the encapsulation layer, and at least part of the touch layer is reused as the third light shielding sub-layer.

3. The display panel according to claim 1, wherein a maximum width of the orthographic projection of the peeping prevention pixel opening on the base substrate in the first direction is a first width, a maximum width of the orthographic projection of the lens structure on the base substrate in the first direction is a second width, and a ratio of the first width to the second width is less than or equal to 0.6.

4. The display panel according to claim 2, wherein the light shielding layer comprises a first light shielding sub-layer, and the lens structure is in direct contact with at least part of the first light shielding sub-layer; or
wherein the light shielding layer comprises a first light shielding sub-layer, the display panel further comprises a first covering layer between the first light shielding sub-layer and the lens structure, and a surface of the lens structure close to the base substrate is spaced apart from a surface of the first light shielding sub-layer away from the base substrate.

5. The display panel according to claim 2, wherein the light-shielding layer comprises a third light shielding sub-layer, and the lens structure is in direct contact with at least part of the third light shielding sub-layer; or
wherein the light shielding layer comprises a third light shielding sub-layer, the display panel further comprises a third covering layer between the third light shielding sub-layer and the lens structure, and a surface of the lens structure close to the base substrate is spaced apart from a surface of the third light shielding sub-layer away from the base substrate.

6. The display panel according to claim 2, wherein a light emitting layer of the peeping prevention sub-pixel comprises a first surface away from the base substrate, the lens structure comprises a second surface close to the base substrate, the first surface is spaced apart from the second surface by a first spacing distance, and the first spacing distance is less than a sum of the first width and the second width.

7. The display panel according to claim 2, wherein the first light shielding sub-layer defines a plurality of first opening regions, and an orthographic projection of a boundary of the peeping prevention pixel opening on the base substrate is surrounded by an orthographic projection of a boundary of a corresponding first opening region on the base substrate; or
wherein the orthographic projection of the peeping prevention pixel opening on the base substrate at least partially overlaps with an orthographic projection of the first light shielding sub-layer on the base substrate.

8. The display panel according to claim 2, wherein the second light shielding sub-layer defines a plurality of second opening regions, and an orthographic projection of a boundary of the peeping prevention pixel opening on the base substrate is surrounded by an orthographic projection of a boundary of a corresponding second opening region on the base substrate; or
wherein the orthographic projection of the peeping prevention pixel opening on the base substrate at least partially overlaps with an orthographic projection of the second light shielding sub-layer on the base substrate.

9. The display panel according to claim 2, wherein an orthographic projection of a first light shielding sub-layer corresponding to a peeping prevention pixel opening on the base substrate completely overlaps with an orthographic projection of a second light shielding sub-layer corresponding to the same peeping prevention pixel opening on the base substrate; or
wherein an orthographic projection of a first light shielding sub-layer corresponding to a peeping prevention pixel opening on the base substrate falls within an orthographic projection of a second light shielding sub-layer corresponding to the same peeping prevention pixel opening on the base substrate.

10. The display panel according to claim 2, wherein the third light shielding sub-layer defines a plurality of third opening regions, and an orthographic projection of the third opening region on the base substrate at least partially overlaps with an orthographic projection of the corresponding lens structure on the base substrate.

11. The display panel according to claim 2, wherein an orthographic projection of a third light shielding sub-layer corresponding to a peeping prevention pixel opening on the base substrate completely overlaps with an orthographic projection of a second light shielding sub-layer corresponding to the same peeping prevention pixel opening on the base substrate; or
wherein an orthographic projection of a third light shielding sub-layer corresponding to a peeping prevention pixel opening on the base substrate falls within an orthographic projection of a second light shielding sub-layer corresponding to the same peeping prevention pixel opening on the base substrate.

12. the display panel according to claim 2, wherein the first light shielding sub-layer has a first thickness, the encapsulation layer has a fourth thickness, and a ratio of the first thickness to the fourth thickness is greater than or equal to 0.05 and less than or equal to 0.5; and/or
wherein the second light shielding layer has a second thickness, the encapsulation layer has a fourth thickness, and a ratio of the second thickness to the fourth thickness is greater than or equal to 0.05 and less than or equal to 0.5,
wherein the first spacing distance is less than twice the fourth thickness.

13. The display panel according to claim 2, wherein the second light shielding sub-layer is made of a metal material having a reflectivity greater than or equal to 20%,
wherein the second light shielding sub-layer has a second thickness, the encapsulation layer has a fourth thickness, and a ratio of the second thickness to the fourth thickness is greater than or equal to 0.005 and less than or equal to 0.5,
wherein the third light shielding sub-layer has a third thickness, and a ratio of the third thickness to the fourth thickness is greater than or equal to 0.005 and less than or equal to 0.5.

14. (canceled)

15. (canceled)

16. The display panel according to claim 6, wherein the first light shielding sub-layer comprises a third surface close to the base substrate, the first surface is spaced apart from the third surface by a third spacing distance, and the third spacing distance is less than or equal to the first spacing distance; and/or
wherein the second light shielding sub-layer comprises a fourth surface close to the base substrate, the first surface is spaced apart from the fourth surface by a fourth spacing distance, and a ratio of the fourth spacing distance to the first width is greater than or equal to 1 and less than or equal to 2,
wherein a ratio of the fourth spacing distance to the third spacing distance is greater than or equal to 0.2 and less than or equal to 0.85.

17. (canceled)

18. The display panel according to claim 2, wherein the touch layer comprises a plurality of touch sub-lines between the plurality of peeping prevention sub-pixels, at least part of the plurality of touch sub-lines are configured to provide touch signals for corresponding peeping prevention sub-pixels, an orthographic projection of at least part of the touch sub-lines on the base substrate have a third width in the first direction, and the third width is less than the first width.

19. The display panel according to claim 2, wherein the third light shielding sub-layer comprises a plurality of third light shielding sub-portions defining the third opening region, and an orthographic projection of the third light shielding sub-portion on the base substrate at least partially overlaps with the orthographic projection of the lens structure on the base substrate,
wherein an orthographic projection of at least part of the third light shielding sub-portions on the base substrate has a fourth width in the first direction, and a ratio of the fourth width to the second width is greater than or equal to 0.2 and less than or equal to 0.8,
wherein the display panel further comprises a fourth covering layer on a side of the lens structure away from the base substrate, wherein a refractive index of a material in the fourth covering layer is less than a refractive index of a material in the lens structure,
wherein a refractive index of a material in the first covering layer is less than a refractive index of a material in the lens structure; and/or
wherein a refractive index of a material in the third covering layer is less than the refractive index of the material in the lens structure.

20. (canceled)

21. (canceled)

22. (canceled)

23. (canceled)

24. The display panel according to claim 1, wherein the display panel comprises a plurality of sharing pixel unit rows and a plurality of peeping prevention pixel unit rows,
wherein the sharing pixel unit row comprises a plurality of sharing pixel units, the sharing pixel unit comprises a plurality of sharing sub-pixels, and
wherein the peeping prevention pixel unit row comprises a plurality of peeping prevention pixel unit, and the peeping prevention pixel unit comprises a plurality of peeping prevention sub-pixels; and the sharing pixel unit rows and the peeping prevention pixel unit rows are arranged alternately.

25. The display panel according to claim 1, wherein the display panel comprises a plurality of sharing pixel units, and the sharing pixel unit comprises a plurality of first sub-pixels, a single second sub-pixel and a plurality of third sub-pixels;
wherein the display panel further comprises a plurality of peeping prevention pixel units, and the peeping prevention pixel unit comprises a plurality of fourth sub-pixels, a plurality of fifth sub-pixels and a plurality of sixth sub-pixels, and
wherein the sharing pixel unit and the peeping prevention pixel unit are arranged correspondingly,
wherein the plurality of first sub-pixels and the plurality of fourth sub-pixels are configured to emit light of the same color, and the plurality of fourth sub-pixels are located in three side regions adjacent to the plurality of first sub-pixels; and/or
wherein the second sub-pixel and the plurality of fifth sub-pixels are configured to emit light of the same color, and the plurality of fifth sub-pixels are located in a side region adjacent to the second sub-pixel; and/or
wherein the plurality of third sub-pixels and the plurality of sixth sub-pixels are configured to emit light of the same color, the plurality of sixth sub-pixels are located in two side regions adjacent to the plurality of third sub-pixels, and the two side regions are located on opposite sides of the third sub-pixels.

26. (canceled)

27. A display device, comprising the display panel according to claim 1.

28. A method of manufacturing a display panel, comprising:
forming a plurality of sub-pixels on a base substrate, wherein the plurality of sub-pixels are arranged on the base substrate in an array in a first direction and a second direction intersecting with the first direction, the plurality of sub-pixels comprise a plurality of sharing sub-pixels and a plurality of peeping prevention sub-pixels, and the peeping prevention sub-pixel comprises a peeping prevention pixel opening;
forming a light shielding layer on a side of the plurality of sub-pixels away from the base substrate, wherein the light shielding layer defines a plurality of opening regions, and an orthographic projection of the opening region on the base substrate at least partially overlaps with an orthographic projection of at least one peeping prevention pixel opening on the base substrate; and
forming a lens structure on a side of the light shielding layer away from the base substrate, wherein an orthographic projection of at least one peeping prevention pixel opening on the base substrate falls within an orthographic projection of the lens structure on the base substrate, and the orthographic projection of the lens structure on the base substrate at least partially overlaps with an orthographic projection of at least one opening region on the base substrate.
